(19) United States
(12) Patent Application Publication
(10) Pub. No.: US 2023/0397474 A1
(43) Pub. Date: Dec. 7, 2023

(54) DISPLAY APPARATUS, ELECTRONIC DEVICE, AND METHOD FOR MANUFACTURING DISPLAY APPARATUS

(71) Applicants: Sony Group Corporation, Tokyo (JP); Sony Semiconductor Solutions Corporation, Kanagawa (JP)

(72) Inventors: Tomoaki Sawabe, Kanagawa (JP); Takashi Yamazaki, Kanagawa (JP); Yu Kato, Kanagawa (JP); Naoya Kasahara, Kanagawa (JP); Masaya Ogura, Kanagawa (JP); Masashi Uchida, Kanagawa (JP)

(21) Appl. No.: 18/033,991

(22) PCT Filed: Nov. 18, 2021
(86) PCT No.: PCT/JP2021/042354

§ 371 Date: Apr. 26, 2023

(30) Foreign Application Priority Data
Nov. 26, 2020 (JP) 2020-195714

(51) Int. Cl. H10K 59/80; H10K 71/20; H10K 71/60

(52) U.S. Cl. CPC H10K 59/871; H10K 71/231; H10K 71/60

(57) ABSTRACT

A display apparatus includes display elements formed on a substrate and arrayed in a two-dimensional matrix, the display elements each having a light emitting unit formed by stacking a lower electrode, an organic layer, and an upper electrode, wherein the lower electrode and the organic layer are provided for each light emitting unit, the substrate includes a groove formed in a part of the substrate positioned between adjacent light emitting units, the groove having a bottom surface and both side surfaces forming a gentle inclination angle with respect to the bottom surface, and a protective film is formed in common on entire surface including an upper surface of the light emitting unit and an upper surface of the groove of the substrate.

### FIELD

The present disclosure relates to a display apparatus, an electronic device, and a method for manufacturing a display apparatus.

### BACKGROUND

A display element including a current driving type light emitting unit and a display apparatus including such a display element are well known. For example, a display element including a light emitting unit composed of an organic electroluminescence element has attracted attention as a display element capable of high-luminance light emission through low-voltage direct current driving.

A display apparatus using organic electroluminescence is a self-luminous type, and further, it has sufficient responsiveness to a high-definition and high-speed video signal. In a display apparatus to be mounted on eyewear such as eyeglasses and goggles, it is required to increase luminance in addition to setting the size of a display element constituting a pixel to about several micrometers to 10 micrometers, for example.

An organic electroluminescent element is configured by sandwiching an organic layer including an organic light emitting layer between a pair of electrodes. The organic layer may be formed in common for every light emitting unit, or may be formed independently for each light emitting unit. From the viewpoint of light utilization efficiency, it is preferable to form the organic layer independently for each light emitting unit. For example, Patent Literature 1 discloses processing an organic layer including an organic light emitting layer through an etching method.

### CITATION LIST

### Patent Literature

Patent Literature 1: JP 2009-170336 A

### SUMMARY

### Technical Problem

In an organic layer including an organic light emitting layer, moisture entering from the outside causes deterioration of light emission properties. For this reason, sealing is performed by covering the entire surface including upper surfaces of display elements with an insulating protective film. However, it is conceivable that a seam caused by non-uniform coverage is generated in a bent part of the protective film to decreases the sealing property.

An object of the present disclosure is to provide a display apparatus having a structure in which the sealing property of a display element is less likely to deteriorate even with a seam caused by non-uniform coverage generated in a bent part of a protective film, an electronic device including the display apparatus, and a method for manufacturing the display apparatus.

### Solution to Problem

A display device according to the present disclosure to solve the above problem is a display device including display elements formed on a substrate and arrayed in a two-dimensional matrix, the display elements each having a light emitting unit formed by stacking a lower electrode, an organic layer, and an upper electrode, wherein
the lower electrode and the organic layer are provided for each light emitting unit,
the substrate includes a groove formed in a part of the substrate positioned between adjacent light emitting units, the groove having a bottom surface and both side surfaces forming a gentle inclination angle with respect to the bottom surface, and
a protective film is formed in common on entire surface including an upper surface of the light emitting unit and an upper surface of the groove of the substrate.

A method for manufacturing a display apparatus according to the present disclosure to solve the above problem is a method for manufacturing a display apparatus including display elements formed on a substrate and arrayed in a two-dimensional matrix, the display elements each having a light emitting unit formed by stacking a lower electrode, an organic layer, and an upper electrode, the method including:
a first step of forming a stacked body in which materials constituting the lower electrode, the organic layer, and the upper electrode are sequentially stacked on the substrate;
a second step of removing a part of the stacked body corresponding to a portion between adjacent light emitting units and thereafter further forming a groove in a part of the substrate being exposed, the groove having a bottom surface and both side surfaces forming a gentle inclination angle with respect to the bottom surface; and
a third step of forming a protective film in common on entire surface including an upper surface of the light emitting unit and an upper surface of the groove of the substrate.

An electronic device according to the present disclosure to solve the above problem is an electronic device including a display apparatus,
the display apparatus including display elements formed on a substrate and arrayed in a two-dimensional matrix, the display elements each having a light emitting unit formed by stacking a lower electrode, an organic layer, and an upper electrode, wherein
the lower electrode and the organic layer are provided for each light emitting unit,
the substrate includes a groove formed in a part of the substrate positioned between adjacent light emitting units, the groove having a bottom surface and both side surfaces forming a gentle inclination angle with respect to the bottom surface, and
a protective film is formed in common on entire surface including an upper surface of the light emitting unit and an upper surface of the groove of the substrate.

### BRIEF DESCRIPTION OF DRAWINGS

FIG. 1 is a schematic diagram of a display apparatus according to a first embodiment.

FIG. 2 is a schematic circuit diagram of a (n, m)th display element (pixel).

FIG. 3 is a schematic and partial sectional view of a substrate and the like for explaining a structure of a display apparatus.

FIG. 4 is a schematic enlarged view for explaining a structure between adjacent light emitting units in FIG. 3.

FIG. 5 is a schematic plan view for explaining a planar arrangement relationship between a groove provided in a part of the substrate positioned between adjacent light emitting units and an organic layer of the light emitting units when a substrate side is viewed from the end surface indicated by A-A in FIG. 3.

FIG. 6 is a schematic plan view for explaining a planar arrangement relationship between the groove provided in a part of the substrate positioned between adjacent light emitting units, the organic layer of the light emitting units, and a lower electrode when the substrate side is viewed from the end surface indicated by A-A in FIG. 3.

FIG. 7 is a schematic and partial sectional view of a substrate and the like for explaining a structure of a display apparatus according to a reference example.

FIG. 8 is a schematic sectional view for explaining a seam caused by non-uniform coverage in a bent part of a protective film between adjacent light emitting units in the display apparatus according to the reference example.

FIG. 9 is a schematic sectional view for explaining a seam caused by non-uniform coverage generated in a bent part of a protective film between adjacent light emitting units in the display apparatus according to the first embodiment.

FIG. 10 is a schematic plan view for explaining a first modification of the arrangement of light emitting units.

FIG. 11 is a schematic plan view for explaining a second modification of the arrangement of light emitting units.

FIG. 12A is a schematic and partial sectional view of a substrate and the like for explaining a method for manufacturing the display apparatus according to the first embodiment.

FIG. 12B is a schematic and partial sectional view of a substrate and the like for explaining the method for manufacturing the display apparatus according to the first embodiment.

FIG. 13 is a schematic and partial sectional view of a substrate and the like for explaining the method for manufacturing the display apparatus according to the first embodiment following FIG. 12.

FIG. 14 is a schematic and partial sectional view of a substrate and the like for explaining the method for manufacturing the display apparatus according to the first embodiment following FIG. 13.

FIG. 15 is a schematic and partial sectional view of a substrate and the like for explaining the method for manufacturing the display apparatus according to the first embodiment following FIG. 14.

FIG. 16 is a schematic and partial sectional view of a substrate and the like for explaining the method for manufacturing the display apparatus according to the first embodiment following FIG. 15.

FIG. 17 is a schematic and partial sectional view of a substrate and the like for explaining the method for manufacturing the display apparatus according to the first embodiment following FIG. 16.

FIG. 18 is a schematic and partial sectional view of a substrate and the like for explaining the method for manufacturing the display apparatus according to the first embodiment following FIG. 17.

FIG. 19 is a schematic and partial sectional view of a substrate and the like for explaining the method for manufacturing the display apparatus according to the first embodiment following FIG. 18.

FIG. 20 is a schematic and partial sectional view of a substrate and the like for explaining the method for manufacturing the display apparatus according to the first embodiment following FIG. 19.

FIG. 21 is a schematic and partial sectional view of a substrate and the like for explaining a structure of a display apparatus according to a second embodiment.

FIG. 22 is a schematic plan view for explaining a planar arrangement relationship between a groove provided in a part of the substrate positioned between adjacent light emitting units, an organic layer of the light emitting units, and a lower electrode when the substrate side is viewed from the end surface indicated by B-B in FIG. 21.

FIG. 23 is a schematic and partial sectional view of a substrate and the like for explaining a method for manufacturing the display apparatus according to the second embodiment.

FIG. 24 is a schematic and partial sectional view of a substrate and the like for explaining the method for manufacturing the display apparatus according to the second embodiment following FIG. 23.

FIG. 25 is a schematic and partial sectional view of a substrate and the like for explaining the method for manufacturing the display apparatus according to the second embodiment following FIG. 24.

FIG. 26 is a schematic and partial sectional view of a substrate and the like for explaining a structure of a display apparatus according to a third embodiment.

FIG. 27 is a schematic and partial sectional view of a substrate and the like for explaining a method for manufacturing the display apparatus according to the third embodiment.

FIG. 28 is a schematic and partial sectional view of a substrate and the like for explaining the method for manufacturing the display apparatus according to the third embodiment following FIG. 27.

FIG. 29 is a schematic and partial sectional view of a substrate and the like for explaining the method for manufacturing the display apparatus according to the third embodiment following FIG. 28.

FIG. 30A is an external view (front view) of a lens interchangeable single-lens reflex digital still camera.

FIG. 30B is an external view (back view) of the lens interchangeable single-lens reflex digital still camera.

FIG. 31 is an external view of a head mounted display.

FIG. 32 is an external view of a see-through head mounted display.

FIG. 33 is a block diagram depicting an example of schematic configuration of a vehicle control system.

FIG. 34 is a diagram of assistance in explaining an example of installation positions of an outside-vehicle information detecting section and an imaging section.

FIG. 35 is a view schematically depicting a general configuration of a surgery room system.

FIG. 36 is a view depicting an example of display of an operation screen image of a centralized operation panel.

FIG. 37 is a view illustrating an example of a state of surgery to which the surgery room system is applied.

FIG. 38 is a block diagram depicting an example of a functional configuration of a camera head and a camera control unit (CCU) depicted in FIG. 37.

### DESCRIPTION OF EMBODIMENTS

Hereinafter, the present disclosure will be described based on embodiments with reference to the drawings. The present disclosure is not limited to the embodiments, and various numerical values and materials in the embodiments are examples. In the following description, the same reference signs will be used for the same elements or elements having the same functions, and redundant description will be omitted. The description will be given in the following order.
1. General description of display apparatus, electronic device, and method for manufacturing display apparatus according to the present disclosure
2. First Embodiment
3. Second Embodiment
4. Third Embodiment
5. Description of electronic device
6. Application Example 1
7. Application Example 2
8. Others

[General Description of Display Apparatus, Electronic Device, and Method for Manufacturing Display Apparatus According to the Present Disclosure]

In the following description, a display apparatus according to the present disclosure, a display apparatus used in an electronic device according to the present disclosure, and a display apparatus obtained by a method for manufacturing a display apparatus according to the present disclosure may be simply referred to as “display apparatus of the present disclosure”. Further, the display apparatus according to the present disclosure, the electronic device according to the present disclosure, and the method of manufacturing a display apparatus according to the present disclosure may be simply referred to as “the present disclosure”.

As described above, a display apparatus according to the present disclosure includes display elements formed on a substrate and arrayed in a two-dimensional matrix, the display elements each having a light emitting unit formed by stacking a lower electrode, an organic layer, and an upper electrode, wherein
the lower electrode and the organic layer are provided for each light emitting unit,
the substrate includes a groove formed in a part of the substrate positioned between adjacent light emitting units, the groove having a bottom surface and both side surfaces forming a gentle inclination angle with respect to the bottom surface, and
a protective film is formed in common on entire surface including an upper surface of the light emitting unit and an upper surface of the groove of the substrate.

According to the present disclosure, a groove having a bottom surface and both side surfaces forming a gentle inclination angle with respect to the bottom surface is formed in a part of the substrate positioned between adjacent light emitting units. Even when a seam caused by non-uniform coverage is generated in a bent part of the protective film, this configuration can separate an end of the seam and the wall surface of the light emitting units. This improves the sealing property of the display elements.

In the display apparatus of the present disclosure, the groove of the substrate may be formed by an etching method. In this case, the side wall surface of the organic layer may be covered with a deposited film containing a substrate constituent as a component. The deposited film is preferably formed on both side surfaces of the groove of the substrate.

When the groove of the substrate is formed by the etching method, a byproduct generated through etching processing adheres to the periphery. When the side wall surface of the organic layer is covered with the deposited film containing a substrate constituent as a component, the end of the seam and the wall surface of the light emitting units further separate from each other. Thus, the sealing property of the display elements further improves.

When moisture enters the organic layer from the outside, light emission characteristics of the organic layer deteriorates. When the side wall surface of the organic layer is covered with the deposited film containing a substrate constituent as a component, moisture hardly permeates the organic layer even when moisture enters through the seam of the protective film. Thus, the light emission characteristics of the organic layer can be more suitably maintained. From the viewpoint of effectively preventing permeation of moisture, the deposited film preferably contains a substrate constituent composed of a silicon compound as a component.

As described above, the groove of the substrate may be formed by an etching method. The etching method is preferably a dry etching method from the viewpoint of attaching the byproduct generated through the etching processing to the periphery. In this case, the groove of the substrate may be formed by a dry etching method using an etching gas such as CF₄, oxygen, argon, or nitrogen.

In the present disclosure including the various preferable configurations described above, the lower electrode may be formed such that its outer edge is not exposed to the side wall surface of the organic layer. In this case, the outer edge of the lower electrode may be covered with an insulating layer.

Alternatively, in the present disclosure including the various preferable configurations, described above, the lower electrode may be formed such that the outer edge is exposed to the side wall surface of the organic layer.

In the present disclosure including the various preferable configurations described above, it is preferable that the upper electrode is provided for each light emitting unit considering the process of forming the groove of the substrate. In such a case, it is necessary to separately form a wiring that connects the upper electrodes of the respective light emitting units to the common power supply line. Alternatively, the upper electrode may be provided in common for every light emitting unit.

In the present disclosure including the various preferable configurations described above, the protective film may be formed using an organic insulating material or an inorganic insulating material. From the viewpoint of coping with miniaturization of the pixel size, it is preferable to form the protective film using an inorganic insulating material. Specifically, the protective film is desirably made of any of silicon oxide, silicon nitride, silicon oxynitride, and aluminum oxide.

The protective film may be formed by a well-known film forming method such as a physical vapor deposition method (PVD method) exemplified by a vacuum vapor deposition method or a sputtering method, various chemical vapor deposition methods (CVD method), and atomic layer deposition methods (ALD method).

A method for manufacturing a display apparatus according to the present disclosure for manufacturing a display apparatus including the various preferable configurations described above includes, as described above:
a first step of forming a stacked body in which materials constituting the lower electrode, the organic layer, and the upper electrode are sequentially stacked on the substrate;
a second step of removing a part of the stacked body corresponding to a portion between adjacent light emitting units and thereafter further forming a groove in a part of the substrate being exposed, the groove having a bottom surface and both side surfaces forming a gentle inclination angle with respect to the bottom surface; and
a third step of forming a protective film in common on entire surface including an upper surface of the light emitting unit and an upper surface of the groove of the substrate.

In the method for manufacturing a display apparatus according to the present disclosure, in the first step, the stacked body in which materials constituting the organic layer and the upper electrode are sequentially stacked may be formed after the lower electrode is formed for each light emitting unit on the substrate. In this case, the first step may include a step of covering an outer edge of the lower electrode with an insulating layer after the lower electrode is formed for each light emitting unit on the substrate.

Alternatively, in the method for manufacturing a display apparatus according to the present disclosure, in the first step, the stacked body in which materials constituting the organic layer and the upper electrode are sequentially stacked is formed after a material layer constituting the lower electrode is formed on the substrate in common for every light emitting unit. In this case, the lower electrode may be formed for each light emitting unit by removing a part of the stacked body corresponding to a portion between adjacent light emitting units in the second step.

In the method for manufacturing a display apparatus according to the present disclosure including the various preferable configurations described above, in the second step, the part of the stacked body corresponding to a portion between adjacent light emitting units is removed by an etching method, thereafter the groove is further formed in a part of the substrate being exposed, the groove having a bottom surface and both side surfaces forming a gentle inclination angle with respect to the bottom surface, and at the same time a side wall surface of the organic layer is covered with a deposited film generated by etching processing.

As described for the display apparatus, the etching method is preferably a dry etching method from the viewpoint of attaching the byproduct generated through the etching processing to the periphery. In this case, it is more desirable to form the film by a dry etching method using an etching gas such as CF₄, oxygen, argon, or nitrogen.

As the support base material constituting the display apparatus, a base material made of a transparent material such as glass or a base material made of a semiconductor material such as silicon may be used. When a glass substrate or the like is used, the transistor that supplies a voltage to the display elements may be formed by forming a semiconductor material layer or the like on a glass substrate and processing the semiconductor material layer or the like. When a base material composed of a semiconductor material such as silicon is used, the transistor or the like may be appropriately formed in a well provided on the base material, for example.

The light emitting unit is preferably a so-called top emission type. The light emitting unit is formed by disposing an organic layer formed by stacking a plurality of material layers between the lower electrode and the upper electrode. The organic layer emits light when a voltage is applied between the lower electrode and the upper electrode. For example, when the lower electrode functions as an anode electrode, the organic layer may have a structure in which a hole injection layer, a hole transport layer, an organic light emitting layer, an electron transport layer, and an electron injection layer are sequentially stacked from the lower electrode side. The hole transport material, the hole transport material, the electron transport material, and the organic light emitting material constituting the organic layer are not limited to particular materials, and known materials may be used.

Examples of the material constituting the electrode of the light emitting unit include metals or alloys such as platinum (Pt), gold (Au), silver (Ag), chromium (Cr), tungsten (W), nickel (Ni), aluminum (Al), copper (Cu), iron (Fe), cobalt (Co), and tantalum (Ta), and transparent conductive materials such as indium-tin oxide (ITO, including Sn-doped In₂O₃, crystalline ITO, and amorphous ITO) and indium-zinc oxide (IZO).

The organic layer may be formed to emit any of red light, green light, and blue light for each light emitting unit. Although this configuration complicates the process of forming the organic layer, this configuration has an advantage of being excellent in light emission efficiency. Although a color filter is basically unnecessary, a color filter corresponding to a color to be displayed may be disposed for improving color purity or the like. The color filter may be formed using, for example, a resin material containing a pigment or a dye.

Alternatively, the organic layer may be formed to emit white light. This configuration has an advantage that a material layer constituting the organic layer can be formed as a common layer in a process of manufacturing the display apparatus. The organic layer that emits white light may have a so-called tandem structure in which a plurality of organic light emitting layers are connected via a charge generation layer or an intermediate electrode. For example, a light emitting unit that emits white light may be configured by stacking organic light emitting layers that emit red light, green light, and blue light, or by stacking organic light emitting layers that emit yellow light and blue light. In the case of performing color display, a color filter corresponding to a color to be displayed may be appropriately disposed corresponding to each light emitting unit.

A driving unit that drives the light emitting units is provided below the substrate on which the light emitting units are arranged, but it is not limited to this configuration. The transistor constituting the driving circuit and the light emitting units may be connected via a contact hole (contact plug) formed in the substrate or the like. The driving circuit may have a known circuit configuration.

In the display apparatus according to the present disclosure, the configuration of the transistor used in the driving circuit is not limited to particular types. The transistor may be a p-channel field effect transistor or an n-channel field effect transistor.

In the display apparatus, a wiring layer including various wirings and electrodes is formed. The layer may be configured by stacking a plurality of material layers on the entire surface of the substrate including the transistor and the like. The wiring, the electrode, and the like included in the wiring layer are separated by an insulating layer. The via for electrically connecting the wiring layer and each lower electrode may be formed, for example, by providing an opening in the insulating layer of the surface layer of the wiring layer, then forming a film of tungsten (W) or the like on the entire surface, and then performing planarization processing.

The metal material layer and the insulating layer constituting the wiring layer may be formed using a material appropriately selected from known inorganic materials and organic materials, and may be formed by, for example, a combination of a known film forming method such as a physical vapor deposition method (PVD method) exemplified by a vacuum vapor deposition method or a sputtering method or various chemical vapor deposition methods (CVD method) and a known patterning method such as an etching method or a lift-off method. The insulating layer constituting the wiring layer may be obtained by the well-known film forming method described above.

The display apparatus may be configured to display a monochrome image or a color image. As the value of the pixels of the display apparatus, some image resolutions such as VGA (640, 480), S-VGA (800, 600), XGA (1024, 768), APRC (1152, 900), S-XGA (1280, 1024), U-XGA (1600, 1200), HD-TV (1920, 1080), Q-XGA (2048, 1536), (3840, 2160), and (7680, 4320) may be exemplified, but the value is not limited to these values.

The array of the light emitting units is not particularly limited as long as the array does not obstruct the implementation of the display apparatus of the present disclosure. Examples of the array of the light emitting units include a square array, a delta array, and a stripe array.

Examples of the display apparatus including the display apparatus of the present disclosure include a television set, a digital still camera, a notebook personal computer, a mobile terminal device such as a mobile phone, a video camera, and a head mounted display.

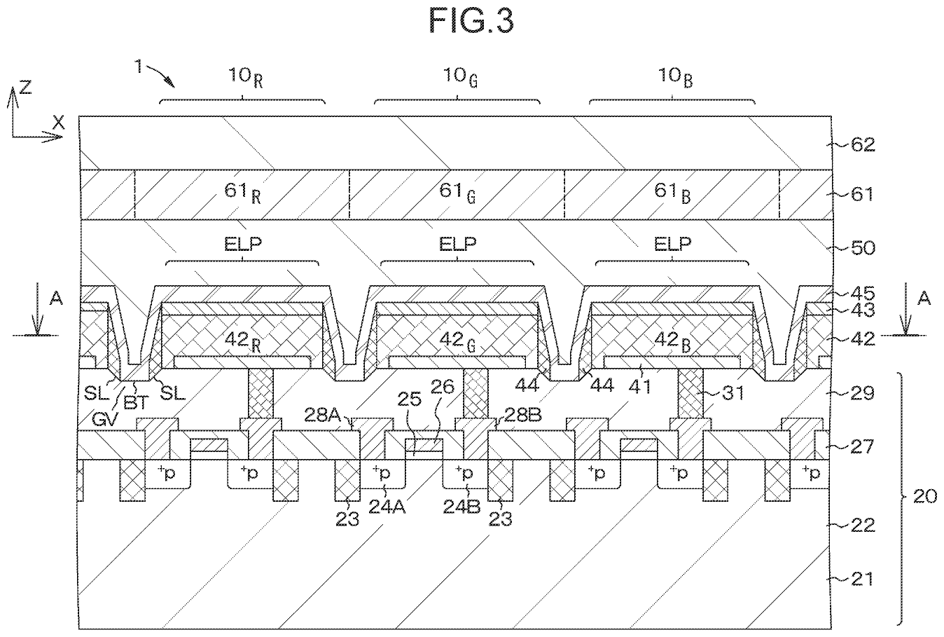

Various conditions in the present specification are satisfied not only when they are strictly satisfied but also when they are substantially satisfied. With respect to satisfaction of the conditions, presence of various variations caused by design or manufacturing of the display apparatus or the like is allowed. In addition, the drawings used in the following description are schematic. For example, FIG. 3 described later illustrates a sectional structure of a display apparatus, but does not illustrate a ratio of a width, a height, a thickness, or the like.

### First Embodiment

A first embodiment relates to a display apparatus, a display apparatus and an electronic device, and a method for manufacturing a display apparatus according to the present disclosure.

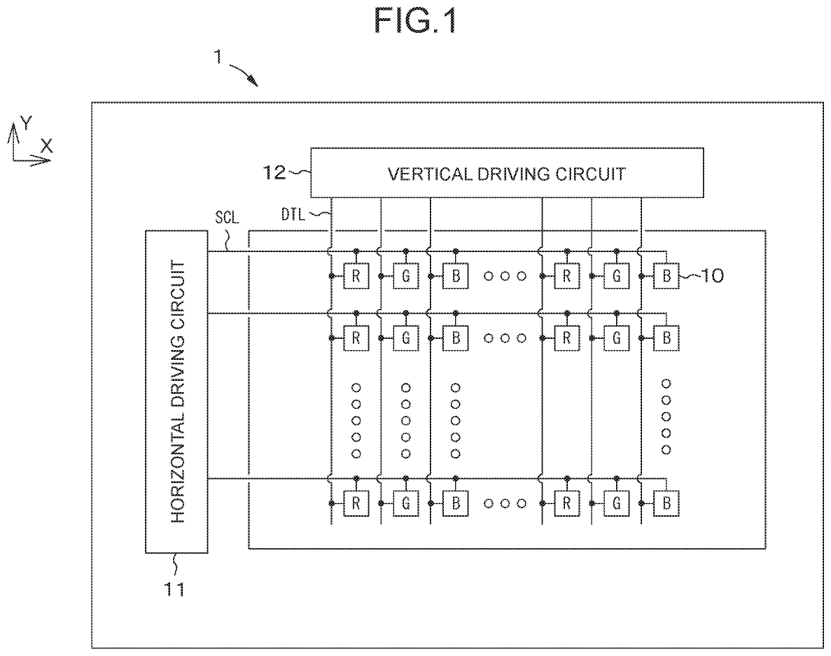

FIG. 1 is a schematic diagram of a display apparatus according to a first embodiment. The display apparatus 1 is an active matrix-type display apparatus. The display apparatus 1 includes display elements 10 arranged in a matrix and various circuits such as a horizontal driving circuit 11 and a vertical driving circuit 12 for driving the display elements 10. Reference sign SCL denotes a scanning line for scanning the display elements 10, and reference sign DTL denotes a signal line for supplying various voltages to the display elements 10.

The display elements 10, the horizontal driving circuit 11, and the vertical driving circuit 12 are integrated in a substrate. That is, the display apparatus 1 is a driver circuit integrated display apparatus. The driver circuit may be provided separately. The display apparatus 1 has, for example, a module shape in which the diagonal width of a display area is about 1 inch. The size of each display element is several micrometers.

As will be described in detail later with reference to FIGS. 3 to 9, in the display apparatus 1, the display elements 10 each having a light emitting unit formed by stacking a lower electrode, an organic layer, and an upper electrode are formed on the substrate and arrayed in a two-dimensional matrix. The lower electrode and the organic layer are provided for each light emitting unit. A groove having a bottom surface and both side surfaces forming a gentle inclination angle with respect to the bottom surface is formed in a part of the substrate positioned between adjacent light emitting units, and a protective film is formed in common on the entire surface including the upper surface of the light emitting unit and the upper surface of the groove of the substrate. Providing the groove can secure the sealing property of the display elements even with a seam caused by non-uniform coverage generated in a bent part of the protective film.

For example, a total of N×M of the display elements 10, N in a row direction (X direction in the drawing) and M in a column direction (Y direction in the drawing), are arranged in a matrix. The display elements 10 arrayed in a two-dimensional matrix form the display region for displaying an image.

The display apparatus 1 is a display apparatus capable of color display. In FIG. 1, display elements corresponding to red display, green display, and blue display are denoted by reference signs R, G, and B, respectively. A group composed of three display elements 10 arranged in the row direction constitutes one color pixel. Thus, when N′=N/3 is satisfied, a total of N′×M color pixels, N′ in the row direction and M in the column direction, are arrayed in the display region.

The number of scanning lines SCL is M. The display elements 10 in the mth row (where m=1, 2, . . . , M) are connected to the mth scanning line SCLₘ and constitute one pixel row. The number of data lines DTL is N. The display elements 10 in the nth column (where n=1, 2, . . . , N) are connected to the nth data line DTLₙ.

Although not illustrated in FIG. 1, the display apparatus 1 includes a power supply line that supplies a driving voltage for each row of the display elements 10 and a common power supply line commonly connected to all the display elements 10.

Hereinafter, the display element 10 positioned in the mth row and the nth column may be referred to as (n, m)th display element 10. Each element constituting the (n, m)th display element 10 may also be referred to as (n, m)th element.

A digital signal indicating gradation corresponding to an image to be displayed is supplied to the vertical driving circuit 12 from, for example, a device not illustrated. The vertical driving circuit 12 generates an analog signal corresponding to the gradation value and supplies the analog signal to the data lines DTL as a video signal. The maximum value of the analog signal to be generated is substantially equal to the power supply voltage supplied to the vertical driving circuit 12, and the amplitude of the signal is about several volts.

The horizontal driving circuit 11 supplies a scanning signal to the scanning lines SCL. With this scanning signal, the display elements 10 are line-sequentially scanned, for example, in units of rows. The analog signal from the data lines DTL is written in the scanned display elements 10, and light is emitted with luminance corresponding to the value.

In the display apparatus 1, N display elements 10 arrayed in the mth row are simultaneously driven. In other words, in the N display elements 10 arranged along the row direction, the light emission/non-light emission timing is controlled in units of rows to which they belong. When the display frame rate of the display apparatus 1 is expressed as FR (times/second), a scanning period per row (so-called horizontal scanning period) when the display apparatus 1 is line-sequentially scanned in units of rows is less than (1/FR)×(1/M) seconds.

The overview of the display apparatus 1 has been described above. Next, a basic configuration of the display element 10 will be described.

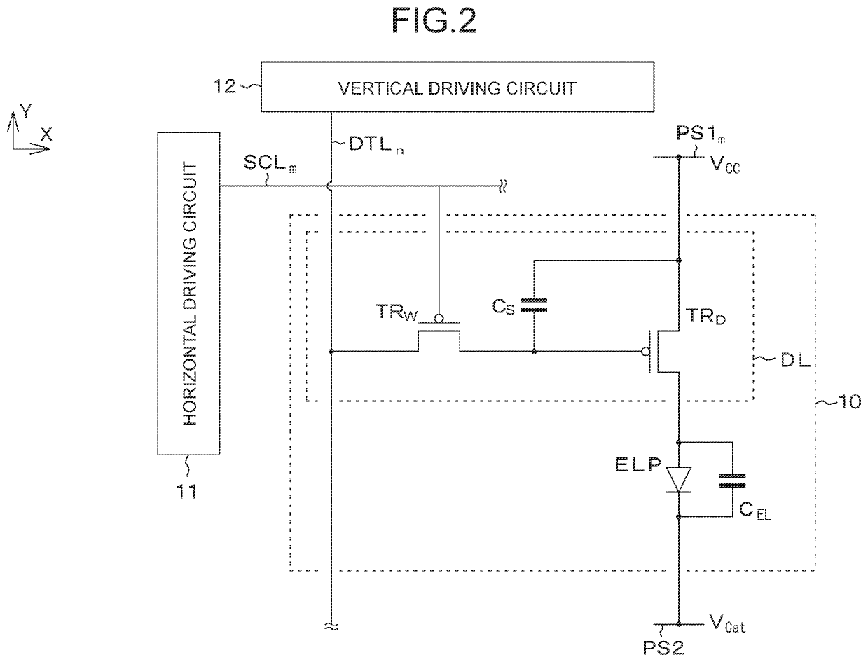

FIG. 2 is a schematic circuit diagram of the (n, m)th display element (pixel).

As illustrated in FIG. 2, the display element 10 includes a current driving type light emitting unit ELP and a driving circuit DL for driving the light emitting unit ELP.

As illustrated in FIG. 2, the driving circuit DL includes two transistors and one capacitor. Reference sign TR_{W} denotes a write transistor for writing a video signal, and reference sign TR_{D} denotes a driving transistor that causes a current to flow through the light emitting unit ELP. These are constituted by p-channel transistors.

In the driving transistor TR_{D}, one source/drain region is connected to a power supply line PS1 to which a driving voltage V_{CC} is supplied. The other source/drain region is connected to the anode electrode of the light emitting unit ELP. The capacitor C_{S} is connected between one source/drain region and the gate electrode.

The cathode electrode of the light emitting unit ELP is connected to a common power supply line PS2 to which a voltage V_{Cat} (for example, ground potential) is supplied. The light emitting unit ELP is composed of an organic electroluminescent element. The capacitance of the light emitting unit ELP is represented by a reference sign C_{EL}. When the capacitance C_{HL} is small and a problem occurs in driving the pixel 10, an auxiliary capacitance connected in parallel to the light emitting unit ELP may be provided as necessary.

In the write transistor TR_{W}, one source/drain region is connected to a data line DTLₙ. The other source/drain region is connected to the gate electrode of the driving transistor TR_{D}.

The conduction state/non-conduction state of the write transistor TR_{W} is controlled by a scanning signal supplied to the scanning line SCLₘ connected to the gate electrode.

A basic operation of the driving circuit DL will be described. The write transistor TR_{W} is brought into a conductive state, and a signal voltage is applied from the data line DTL to the gate electrode of the driving transistor TR_{D}. The capacitor C_{S} holds a voltage corresponding to the signal voltage. The capacitor C_{S} holds V_{gs} (potential difference between the gate electrode and the source region) of the driving transistor TR_{D}.

Next, the write transistor TR_{W} is brought into a non-conductive state. A current represented by the following Formula (1) flows through the driving transistor TR_{D} according to V_{gs} held in the capacitor C_{S}.

For the driving transistor TR_{D}, the signs represent the following values.
μ: effective mobility
L: channel length
W: channel width
V_{gs}: potential difference between gate electrode and source region
Vₜₕ: threshold voltage
Cₒₓ: (relative dielectric constant of gate insulating layer)×(dielectric constant of vacuum)/(thickness of gate insulating layer)

k≡(1/2)·(W/L)·Cₒₓ

I_{ds}=k·μ·(V_{gs}−Vₜₕ)² (1)

The drain current I_{ds} flowing through the light emitting unit ELP causes the light emitting unit ELP to emit light. Further, the light emission state (luminance) of the light emitting unit ELP is controlled by the magnitude of the value of the drain current I_{ds}.

The basic configuration of the display element 10 has been described above. Next, a three-dimensional arrangement relationship of various components constituting the display apparatus 1 will be described.

FIG. 3 is a schematic and partial sectional view of a substrate and the like for explaining the structure of the display apparatus.

First, a substrate 20 will be described. Reference sign 21 denotes a p-type base material made of silicon, for example. An n-type common well region 22 is formed in the base material 21. The various transistors of the driving circuit DL are disposed in the common well region 22. For convenience of illustration, only the driving transistor TR_{D} is illustrated in FIG. 3. Reference sign 23 denotes an element isolation region that defines each transistor, and reference numerals 24A, 24B denote a pair of source/drain regions of the driving transistor TR_{W}. A part sandwiched between the pair of source/drain regions 24A, 24B forms a channel region.

A gate insulating film 25 is formed on the channel region, and a gate electrode 26 is formed on the gate insulating film 25. The gate insulating film 25 may be formed using, for example, silicon oxide (SiOₓ), silicon nitride (SiNₓ), or the like. An interlayer insulating film 27 is formed on the entire surface including the upper surface of the gate electrode 26. The interlayer insulating film 27 may be formed using, for example, silicon oxide (SiOₓ), silicon nitride (SiNₓ), silicon oxynitride (SiOₓN_{y}), or the like.

Source/drain electrodes 28A, 28B are connected to the source/drain regions 24A, 24B of the transistor via an opening provided in the interlayer insulating film 27. A wiring layer 29 is formed on the entire surface including the upper surfaces of the source/drain electrodes 28A, 28B. The wiring layer 29 has a configuration in which various wirings and the like are included in a stacked insulating film, but the configuration is simplified in the drawing. The upper layer part of the wiring layer 29 is made of, for example, an insulating film made of silicon oxide.

The substrate 20 has been described above. Subsequently, a configuration of the display apparatus 1 including the display elements 10 formed and arrayed on the substrate 20 will be described.

First, the stacked structure of the display element 10 will be described. The light emitting unit ELP formed by stacking a lower electrode 41, an organic layer 42, and an upper electrode 43 is disposed on the substrate 20. More specifically, the light emitting unit ELP is formed on the wiring layer 29. The lower electrode 41 is connected to the other source/drain electrode 28B of the driving transistor TR_{D} via a via 31 provided in the wiring layer 29.

The lower electrode 41 and the organic layer 42 are provided for each light emitting unit ELP. The upper electrode 43 is also provided for each light emitting unit ELP. The lower electrode 41 is formed of, for example, an Al—Cu alloy. The upper electrode 43 is made of a transparent conductive material such as ITO.

In the organic layer 42, an organic layer 42_{R} that emits light in red, an organic layer 42_{G} that emits light in green, and an organic layer 42_{B} that emits light in blue are formed according to the color to be displayed by the pixel. The lower electrode 41 is formed such that the outer edge is not exposed to a side wall surface of the organic layer 42.

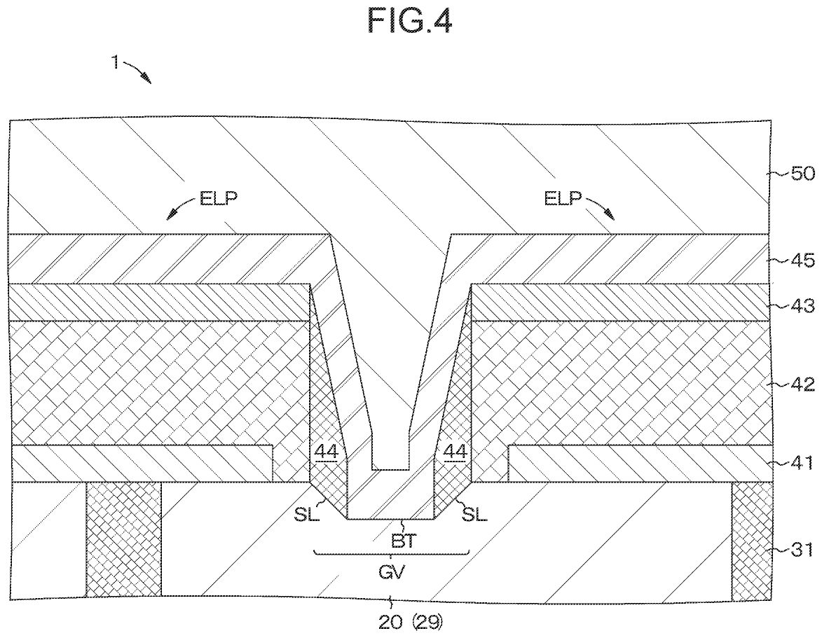

FIG. 4 is a schematic enlarged view for explaining a structure between adjacent light emitting units in FIG. 3.

A groove GV has a bottom surface BT and both side surfaces SL forming a gentle inclination angle with respect to the bottom surface BT. The groove GV is formed by an etching method. The side wall surface of the organic layer 42 is covered with a deposited film 44 containing a substrate constituent as a component. The deposited film 44 is formed on both side surfaces SL of the groove GV of the substrate 20.

When the size of each display element is about several micrometers, the width of the groove GV is about 0.5 micrometers, and the depth of the GV is about 5 nanometers to 50 nanometers. The inclination angle of the side surfaces SL is about 30 degrees, for example.

The deposited film 44 is formed mainly by depositing a substrate constituent when the groove GV of the substrate 20 is formed by an etching method. Since the upper layer part of the wiring layer 29 is formed of an insulating film made of silicon oxide, the deposited film 44 contains a substrate constituent made of a silicon compound as a component.

The stacked structure of the display element 10 has been described above. Next, the planar arrangement relationship of the groove GV, the organic layer 42, and the lower electrode will be described.

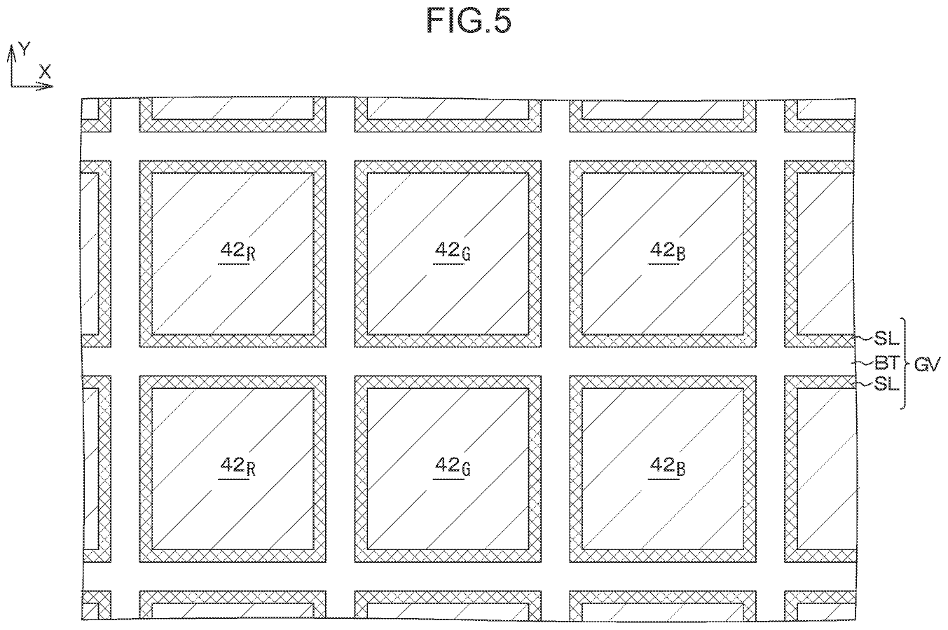

FIG. 5 is a schematic plan view for explaining a planar arrangement relationship between the groove provided in a part of the substrate positioned between adjacent light emitting units and the organic layer of the light emitting units when a substrate side is viewed from the end surface indicated by A-A in FIG. 3. In consideration of readability, the portion of the organic layer is hatched with upward oblique lines, and the portion of the inclined surface of the groove is hatched with cross lines.

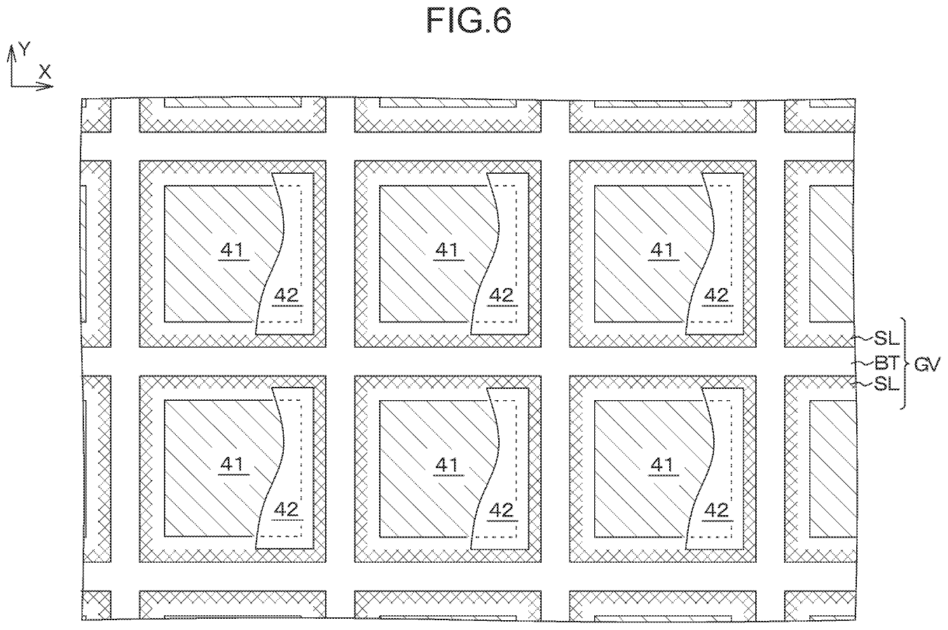

FIG. 6 is a schematic plan view for explaining a planar arrangement relationship between the groove provided in a part of the substrate positioned between adjacent light emitting units, the organic layer of the light emitting units, and the lower electrode when the substrate side is viewed from the end surface indicated by A-A in FIG. 3. For convenience of illustration, a part of the organic layer is cut out in FIG. 6. In consideration of readability as in FIG. 5, the portion of the lower electrode is hatched with downward oblique lines, and the portion of the inclined surface of the groove is hatched with cross lines.

As illustrated in FIG. 5, the organic layers 42 are arranged in a square matrix at intervals. As illustrated in FIG. 6, the lower electrode 41 is disposed to be planarly included in each organic layer 42.

Then, as illustrated in FIG. 5, the inclined surface of the groove GV is located around the organic layer 42. As described above, the deposited film 44 is formed on both side surfaces SL of the groove GV of the substrate. Thus, the entire side wall surface of the organic layer 42 is covered with the deposited film 44.

The planar arrangement relationship of the groove GV, the organic layer 42, and the lower electrode has been described above. Subsequently, the display apparatus 1 will be described.

As illustrated in FIG. 3, a protective film 45 is formed in common on the entire surface including the upper surface of the light emitting unit ELP and the upper surface of the groove GV of the substrate 20. The protective film 45 is formed of, for example, a vapor deposition film of silicon oxide which is an inorganic insulating material.

A planarization layer 50 made of, for example, a transparent material is provided on the protective film 45, and a color filter 61 corresponding to an emission color is disposed thereon for improving color purity and the like. Although not illustrated, wiring that connects the common power supply line PS2 illustrated in FIG. 2 and the upper electrode 43 of each light emitting unit ELP is provided in the planarization layer 50.

The color filter 61 includes a red color filter 61_{R} corresponding to the light emitting unit ELP that emits red light, a green color filter 61_{G} corresponding to the light emitting unit ELP that emits green light, and a blue color filter 61_{B} corresponding to the light emitting unit ELP that emits blue light. A counter substrate 62 made of, for example, a glass material is disposed on the color filter 61.

The light emitted from the organic layer 42 of the light emitting unit ELP reaches the color filter 61 via the upper electrode 43, the protective film 45, and the planarization layer 50. The light through the color filter 61 is emitted from the counter substrate 62 to display an image. The display apparatus 1 is a display apparatus having a so-called top emission structure.

The configuration of the display apparatus 1 has been described above.

As described above, the groove GV is formed in a part the substrate 20 positioned between adjacent light emitting units ELP. Providing the groove GV can secure the sealing property of the display elements even with a seam caused by non-uniform coverage generated in a bent part of the protective film.

Here, to help understanding of the present disclosure, features of the display apparatus 1 will be described in comparison with a display apparatus according to a reference example.

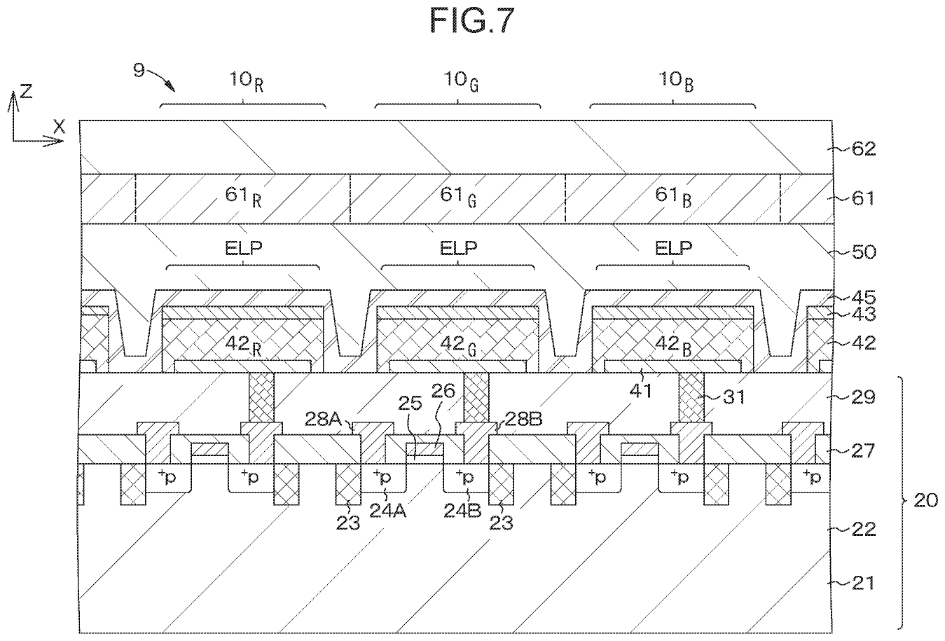

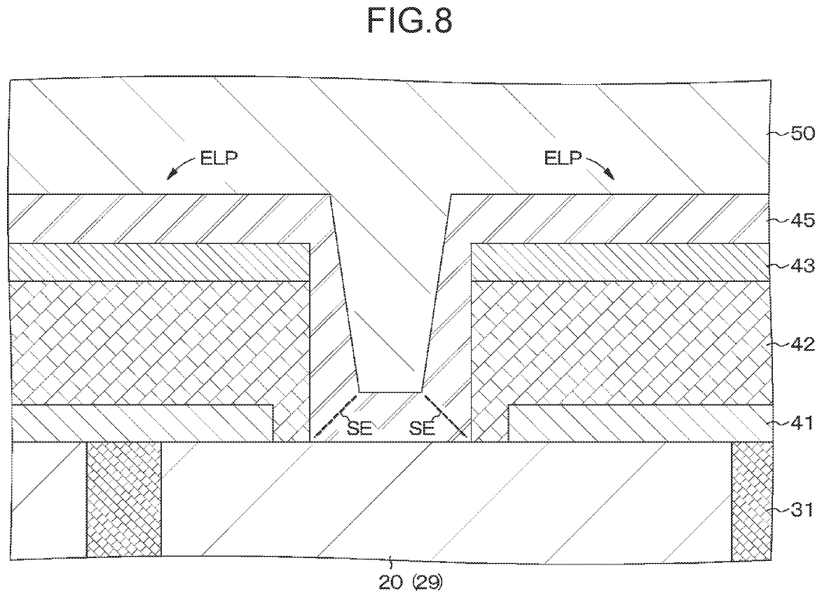

FIG. 7 is a schematic and partial sectional view of a substrate and the like for explaining a structure of a display apparatus according to a reference example. FIG. 8 is a schematic sectional view for explaining a seam caused by non-uniform coverage generated in a bent part of the protective film between adjacent light emitting units in the display apparatus according to the reference example.

A display apparatus 9 of the reference example illustrated in FIG. 7 has the same configuration as the display apparatus 1 except that the groove GV of the substrate is omitted.

When the protective film 45 is formed on an uneven surface, non-uniform coverage is generated in a bent part, and thus a seam is likely to occur. Thus, as illustrated in FIG. 8, a seam is likely to be generated in the protective film 45 at a portion where the side wall surface of the organic layer 42 and the surface of the substrate 20 intersect. The broken line part indicated by reference sign SE schematically indicates the seam of the protective film 45.

In the portion where the seam is generated in the protective film 45, the sealing property relatively deteriorates. Then, in the display apparatus 9 of the reference example, since an end of the seam is in a state of being close to the side wall surface of the organic layer 42, the sealing property of the display element deteriorates. Thus, there is also a problem that moisture is likely to permeate the organic layer 42.

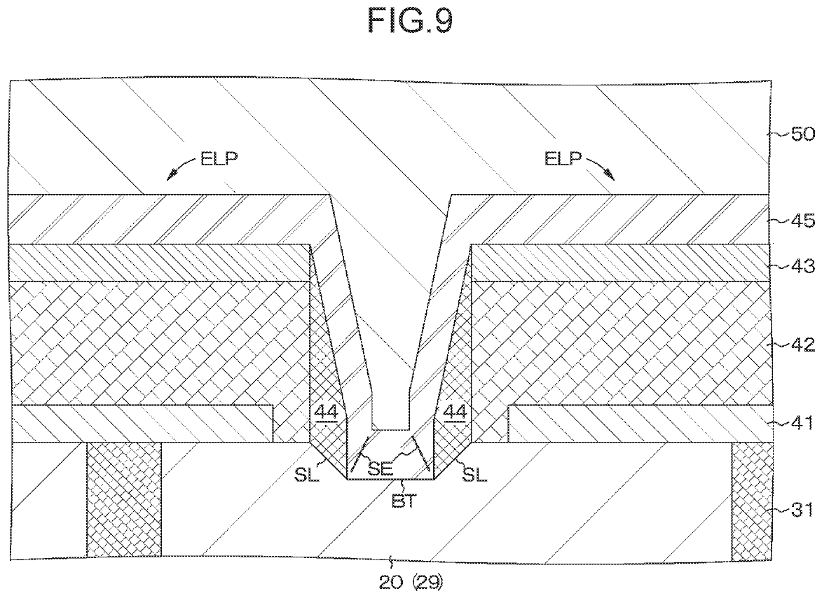

FIG. 9 is a schematic sectional view for explaining a seam caused by non-uniform coverage generated in a bent part of the protective film between adjacent light emitting units in the display apparatus according to the first embodiment.

A seam is likely to be generated in a bent part of the protective film 45 also in the display apparatus 1 according to the first embodiment. However, since the groove GV is provided in the substrate 20, the seam is formed such that an end thereof is relatively separated from the side wall surface of the organic layer 42. In addition, since the side wall surface of the organic layer 42 is covered with the deposited film 44, the end of the seam is further separated from the side wall surface of the organic layer 42. Thus, even with a seam caused by non-uniform coverage generated in a bent part of the protective film 45, the sealing property of the display element is less likely to deteriorate.

In addition, since the side wall surface of the organic layer 42 is covered with the deposited film 44 containing a substrate constituent as a component, moisture through the seam hardly permeates the organic layer 42. Thus, deterioration of the characteristics of the organic layer 42 due to permeation of moisture can be prevented.

Although the organic layer 42 and the lower electrode 41 are arranged in a square matrix, this is merely an example. The same applies to other embodiments described later. Hereinafter, modifications will be described.

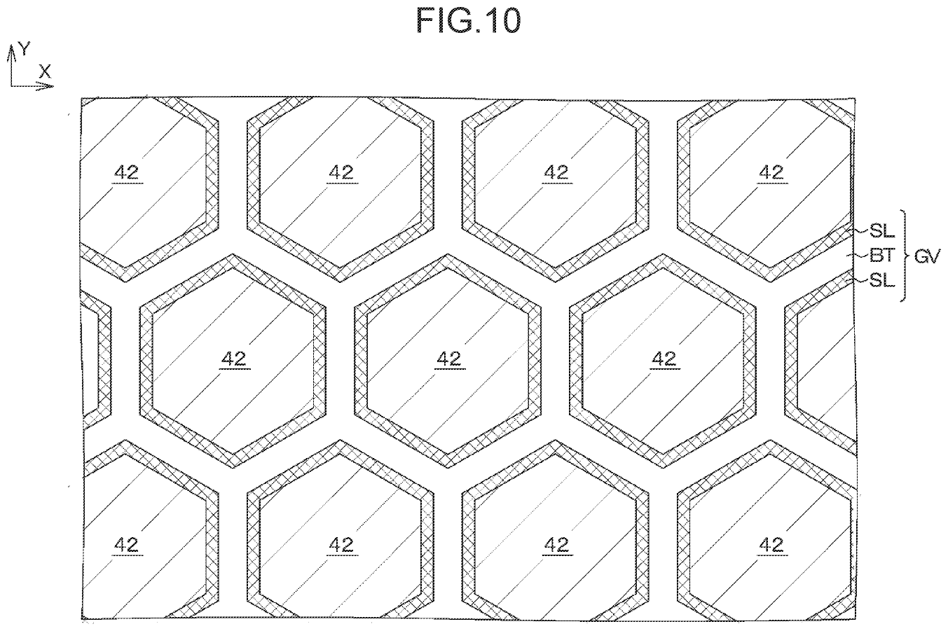

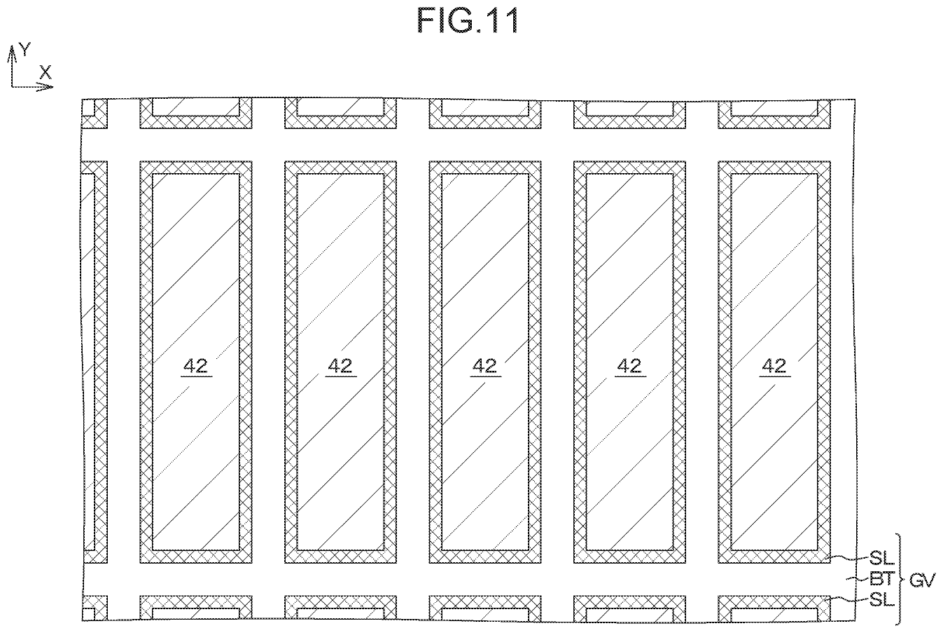

FIG. 10 is a schematic plan view for explaining a first modification of the arrangement of light emitting units. FIG. 11 is a schematic plan view for explaining a second modification of the arrangement of light emitting units.

The example illustrated in FIG. 10 is a configuration of a so-called delta array, and the planar shape of the organic layer 42 is a hexagon. The inclined surface SL of the groove GV is formed to cover the periphery of the organic layer 42. FIG. 11 illustrates a configuration of a so-called stripe array, and the planer shape of the organic layer 42 is a rectangle having a long side in a column direction. In this configuration as well, the inclined surface SL of the groove GV is formed to cover the periphery of the organic layer 42.

Next, a method for manufacturing the display apparatus 1 will be described. A method for manufacturing the display apparatus 1 includes:
a first step of forming a stacked body in which materials constituting the lower electrode, the organic layer, and the upper electrode are sequentially stacked on the substrate;
a second step of removing a part of the stacked body corresponding to a portion between adjacent light emitting units and thereafter further forming a groove in a part of the substrate being exposed, the groove having a bottom surface and both side surfaces forming a gentle inclination angle with respect to the bottom surface; and
a third step of forming a protective film in common on entire surface including an upper surface of the light emitting unit and an upper surface of the groove of the substrate.

In the first step, the stacked body in which materials constituting the organic layer and the upper electrode are sequentially stacked is formed after the lower electrode is formed for each light emitting unit on the substrate. In the second step, the part of the stacked body corresponding to a portion between adjacent light emitting units is removed by an etching method, then the groove is further formed in a part of the substrate being exposed, the groove having a bottom surface and both side surfaces forming a gentle inclination angle with respect to the bottom surface, and at the same time a side wall surface of the organic layer is covered with a deposited film generated by etching processing.

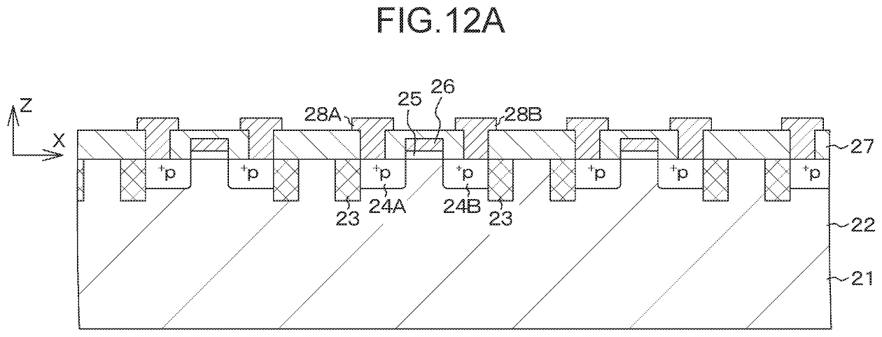

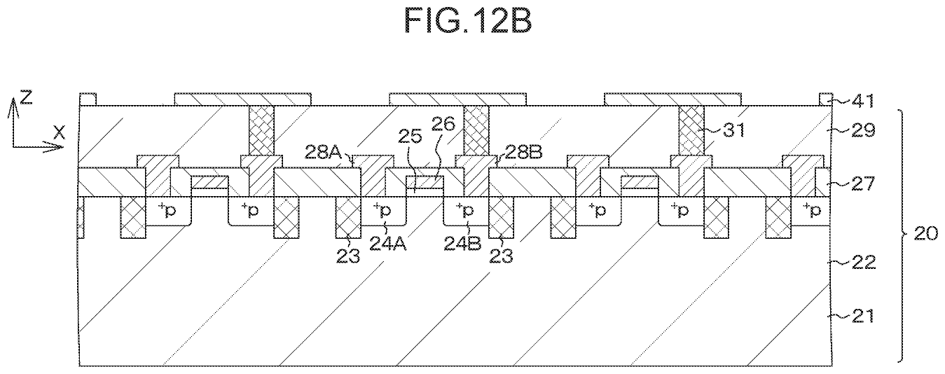

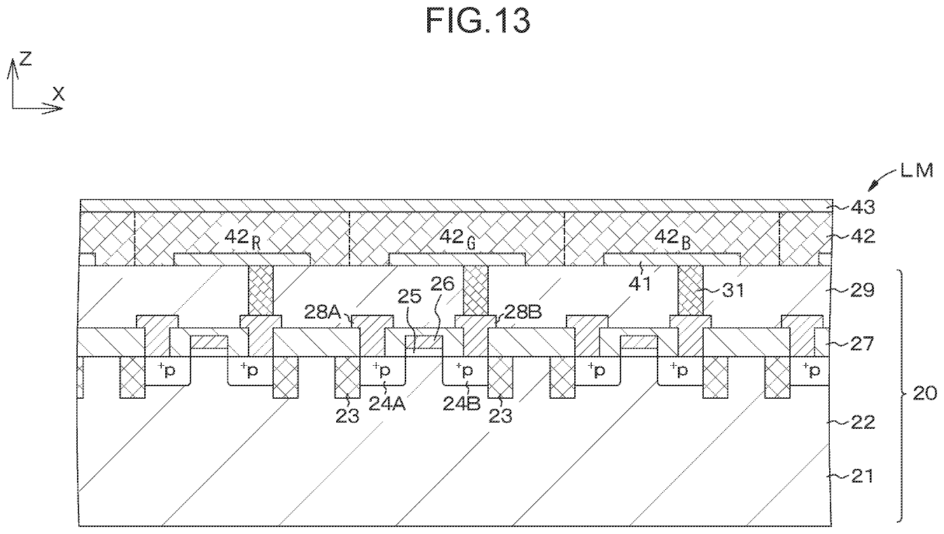

FIGS. 12 to 20 are schematic and partial sectional views of a substrate and the like for explaining the method for manufacturing the display apparatus according to the first embodiment. Hereinafter, the method for manufacturing the display apparatus 1 will be described in detail.

[Step-100] (See FIGS. 12A, 12B, and 13)

First, prepare the base material 21 on which transistors are formed (see FIG. 12A), and form the wiring layer 29 thereon by a well-known film forming method or patterning method. Next, form the via 31 penetrating the wiring layer 29. Thereafter, form a conductive film made of a metal material on the wiring layer 29, and then perform patterning through a known patterning method to form the lower electrode 41 (see FIG. 12B).

Next, form the organic layer 42 on the entire surface including the upper surface of the lower electrode 41. Thereafter, form a conductive material layer (indicated by reference sign 43 for convenience) constituting the upper electrode 43 on the organic layer 42 (see FIG. 13).

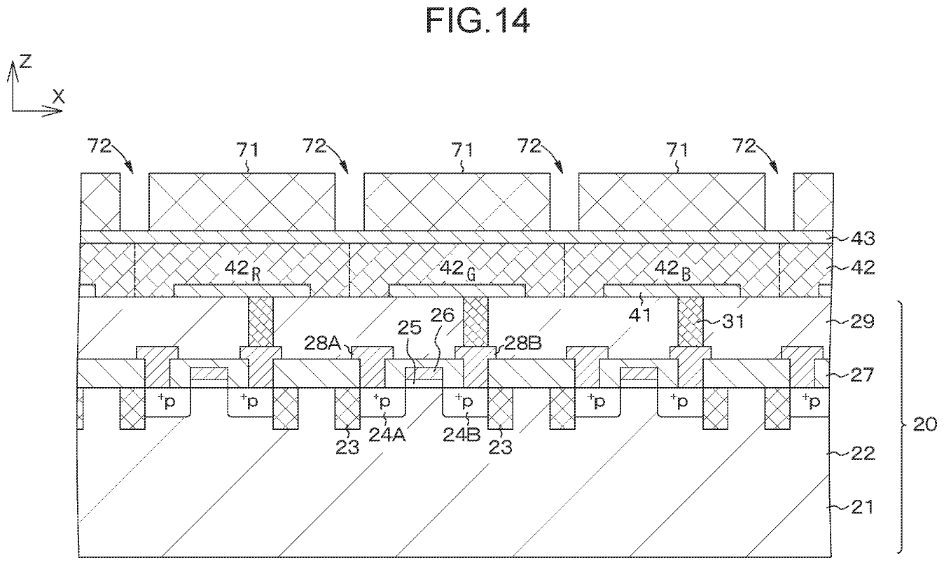

Through the above steps, a stacked body LM in which the materials constituting the lower electrode 41, the organic layer 42, and the upper electrode 43 are sequentially stacked is formed on the substrate 20.

[Step-110] (See FIGS. 14, 15, 16, 17, and 18)

Next, remove the stacked body LM corresponding to the portion between adjacent light emitting units ELP, then further form a groove having a bottom surface and both side surfaces forming a gentle inclination angle with respect to the bottom surface in the part of the substrate 20 being exposed.

First, form a mask 71 that covers a region corresponding to the light emitting unit ELP on the conductive material layer constituting the upper electrode 43. Reference sign 72 denotes an opening of the mask (see FIG. 14).

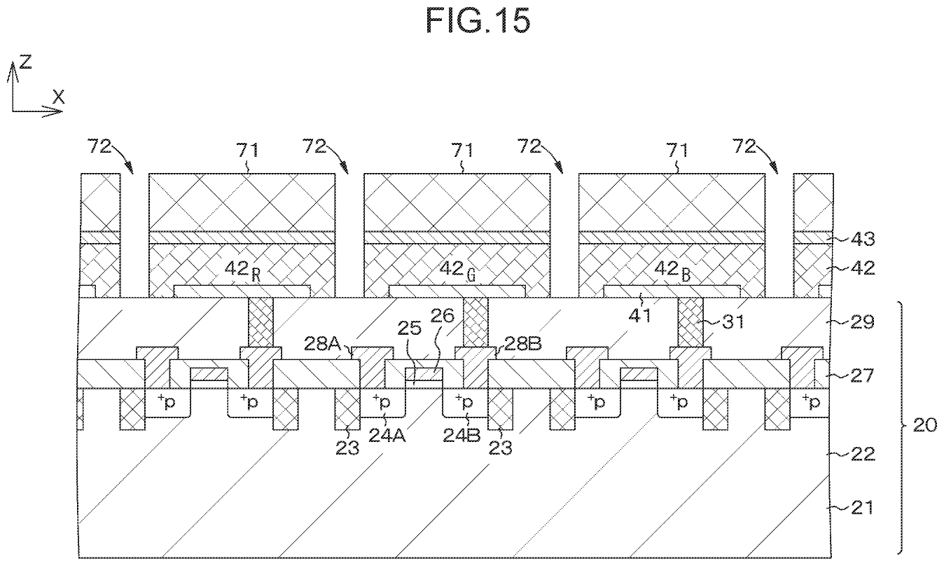

Next, remove the stacked body LM in the portion of the mask opening 72 using, for example, a dry etching method. FIG. 15 illustrates the stage where the surface of the substrate 20 is exposed through etching.

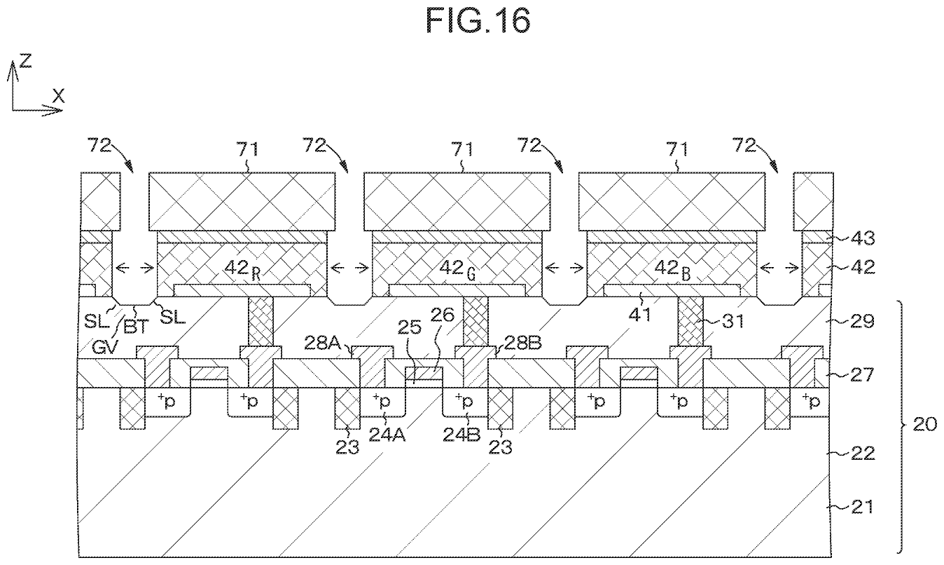

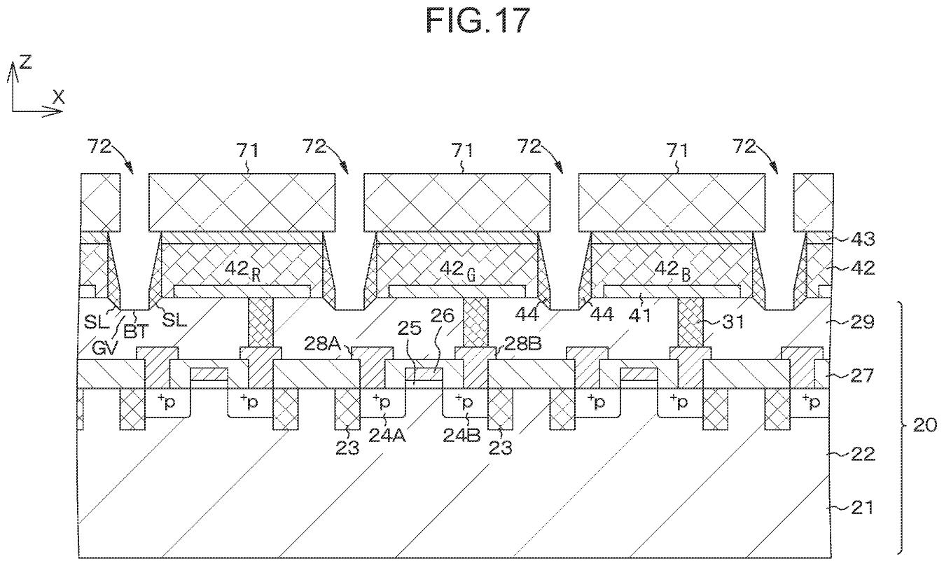

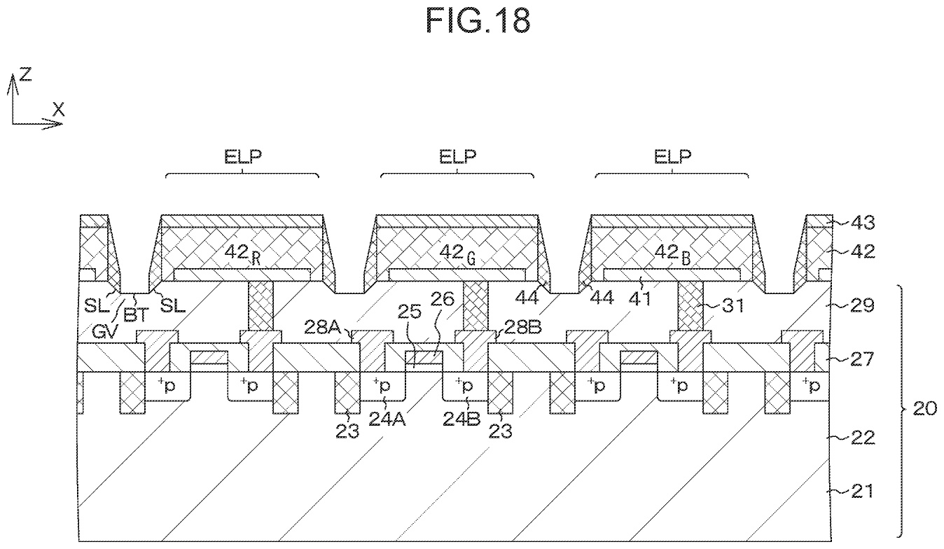

Further perform etching to form a groove on the surface (more specifically, the surface of the wiring layer 29) of the substrate 20. Since the wall surface of the organic layer 42 gradually moves back through side etching (see FIG. 16), the groove GV is formed to have a bottom surface BT and both side surfaces SL forming a gentle inclination angle with respect to the bottom surface BT. In addition, since a byproduct generated through etching processing of the wiring layer 29 adheres to the periphery, the protective film 45 is formed on a side wall surface of the organic layer 42 (see FIG. 17). Thereafter, remove the mask 71 (see FIG. 18).

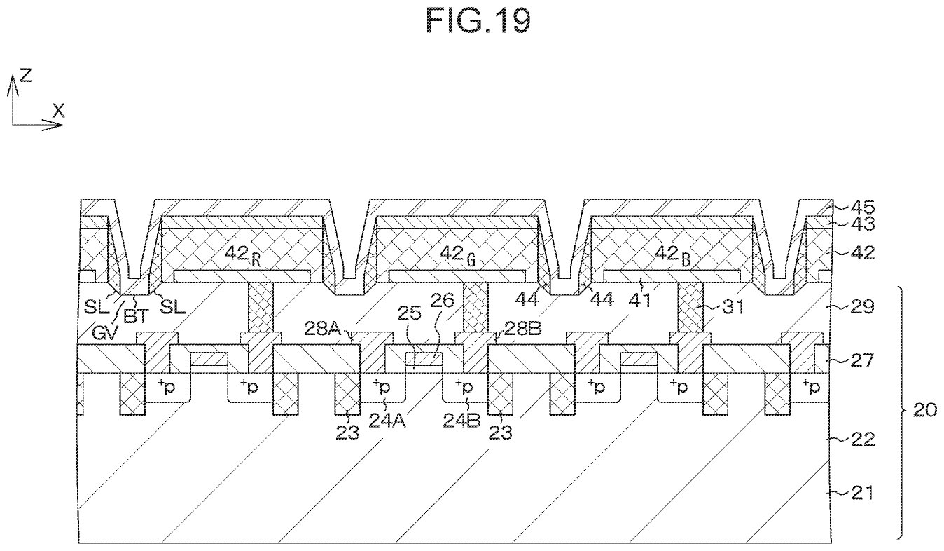

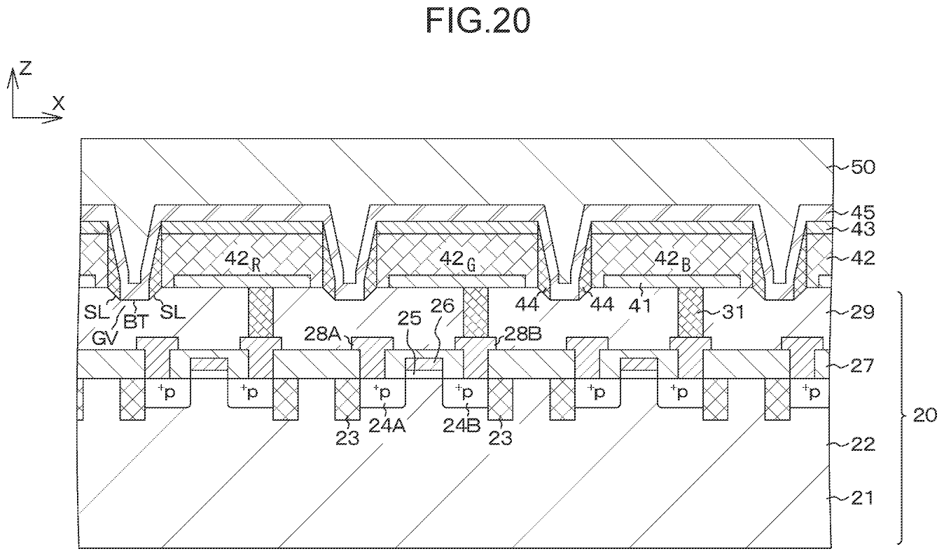

Through the above steps, the stacked body LM corresponding to the portion between the light emitting unit ELP and the light emitting unit ELP is removed, and the light emitting units ELP arranged in a matrix are formed. In addition, the groove GV having the bottom surface BT and the both side surfaces SL forming a gentle inclination angle with respect to the bottom surface BT is formed in the exposed portion of the substrate 20.

[Step-120] (see FIGS. 19 and 20)

Next, form the protective film 45 in common on the entire surface including the upper surface of the light emitting unit ELP and the upper surface of the groove GV of the substrate 20 (see FIG. 19), and then form the planarization layer 50 on the entire surface (see FIG. 20).

Thereafter, by sequentially disposing the color filter 61 and the counter substrate 62 on the planarization layer 50, the display apparatus 1 illustrated in FIG. 3 may be obtained.

### Second Embodiment

A second embodiment also relates to the display apparatus, the display apparatus and the electronic device, and the method for manufacturing a display apparatus according to the present disclosure.

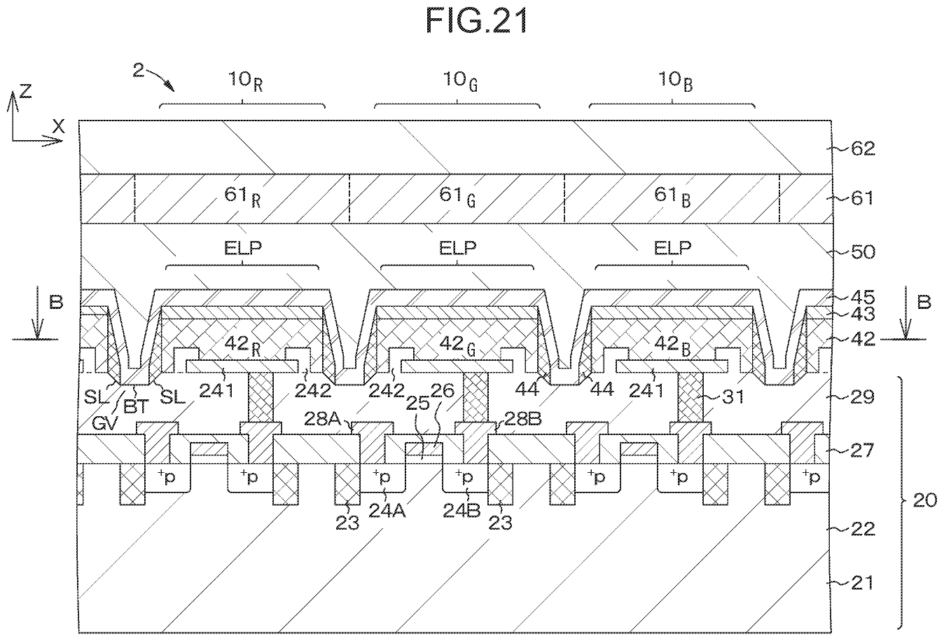

FIG. 21 is a schematic and partial sectional view of a substrate and the like for explaining a structure of a display apparatus according to the second embodiment, corresponding to FIG. 3 referred to in the first embodiment. In the schematic view of the display apparatus according to the second embodiment, the display apparatus 1 is replaced with a display apparatus 2 in FIG. 1.

As in the first embodiment, a lower electrode 241 in the display apparatus 2 is formed such that the outer edge is not exposed to a side wall surface of the organic layer 42. However, the display apparatus 2 is different from the display apparatus 1 described in the first embodiment in that the outer edge of the lower electrode 241 is covered with an insulating layer 242.

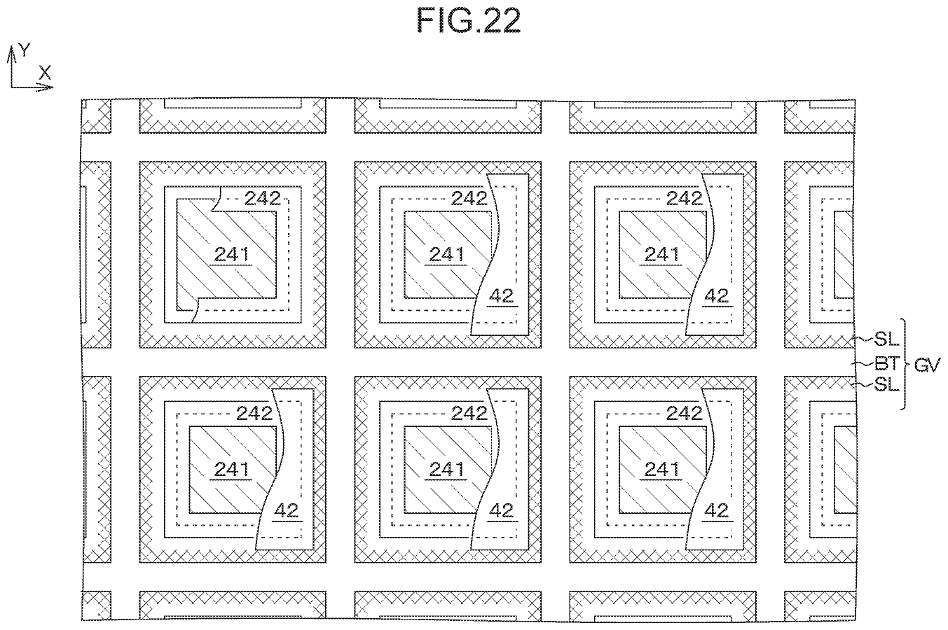

FIG. 22 is a schematic plan view for explaining a planar arrangement relationship between the groove provided in a part of the substrate positioned between adjacent light emitting units, the organic layer of the light emitting units, and the lower electrode when the substrate side is viewed from the end surface indicated by B-B in FIG. 21. To illustrate the stacked relationship, only a part of the organic layer 42 is illustrated in FIG. 22, and a part of the insulating layer 242 is cut out.

As illustrated in the drawing, the organic layers 42 are arranged in a square matrix at intervals. The lower electrode 241 is disposed to be planarly included in the organic layer 42.

The outer edge of the lower electrode 241 is covered with the insulating layer 242. The insulating layer 242 may be formed using, for example, a material different in type from the surface layer of the wiring layer 29.

In the display apparatus 2, since the outer edge of the lower electrode 241 is covered with the insulating layer 242, the light emitting unit is defined by the insulating layer 242. Since the end surface of the light emitting unit is moved back more than the processed end surface, the distance from the seam increases. For this reason, an effect of improving the resistance to moisture entry from the seam can be obtained.

Then, as illustrated in the drawing, the inclined surface SL of the groove GV is positioned at the periphery of the organic layer 42. As in the first embodiment, the deposited film 44 is formed on the side surface SL of the groove GV of the substrate. Thus, the entire side wall surface of the organic layer 42 is covered with the deposited film 44.

Next, a method for manufacturing the display apparatus 2 will be described. A method for manufacturing the display apparatus 2 includes, in the same manner as in the first embodiment:
a first step of forming a stacked body in which materials constituting the lower electrode, the organic layer, and the upper electrode are sequentially stacked on the substrate;
a second step of removing a part of the stacked body corresponding to a portion between adjacent light emitting units and thereafter further forming a groove in a part of the substrate being exposed, the groove having a bottom surface and both side surfaces forming a gentle inclination angle with respect to the bottom surface; and
a third step of forming a protective film in common on entire surface including an upper surface of the light emitting unit and an upper surface of the groove of the substrate.

In the first step, the stacked body in which materials constituting the organic layer and the upper electrode are sequentially stacked is formed after the lower electrode is formed for each light emitting unit on the substrate. Further, the first step includes a step of covering an outer edge of the lower electrode with an insulating layer after the lower electrode is formed for each light emitting unit on the substrate. In the second step, the part of the stacked body corresponding to a portion between adjacent light emitting units is removed by an etching method, then the groove is further formed in a part of the substrate being exposed, the groove having a bottom surface and both side surfaces forming a gentle inclination angle with respect to the bottom surface, and at the same time a side wall surface of the organic layer is covered with a deposited film generated by etching processing.

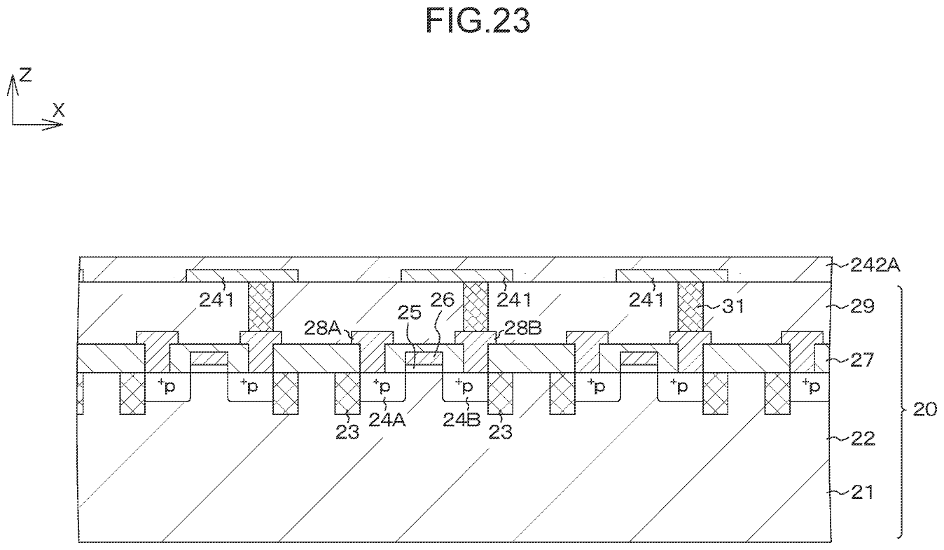

FIGS. 23 to 25 are schematic and partial sectional views of a substrate and the like for explaining the method for manufacturing the display apparatus according to the second embodiment. Hereinafter, the method for manufacturing the display apparatus 2 will be described in detail.

[Step-200] (See FIGS. 23, 24, and 25)

First, perform the same steps as those up to FIG. 12B referred to in [Step-100] described in the first embodiment with the lower electrode 41 being replaced with the lower electrode 241. Subsequently, form an insulating material layer 242A on the entire surface including the upper surface of the lower electrode 241 (see FIG. 23). From the viewpoint of patterning of the insulating material layer 242A to be subsequently performed, the insulating material layer 242A is preferably formed of an insulator of a type different from the surface layer of the wiring layer 29.

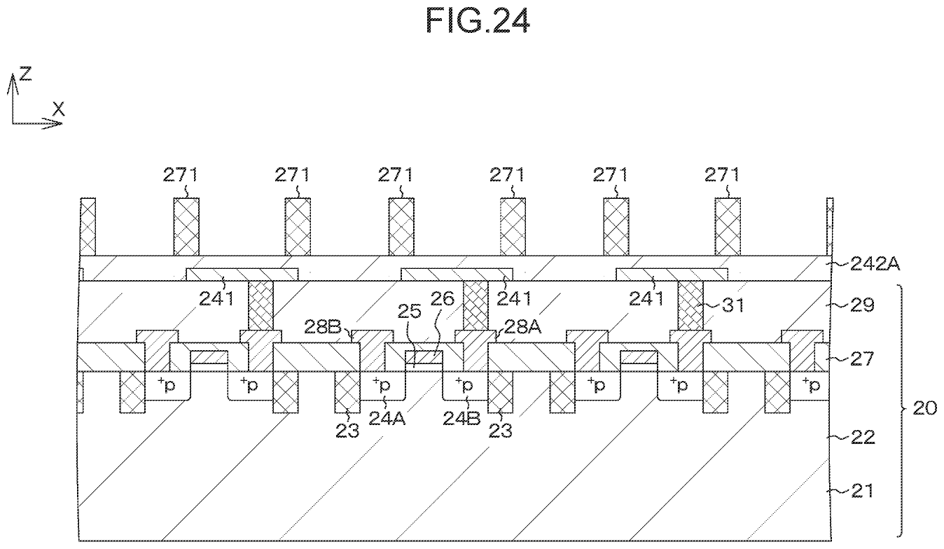

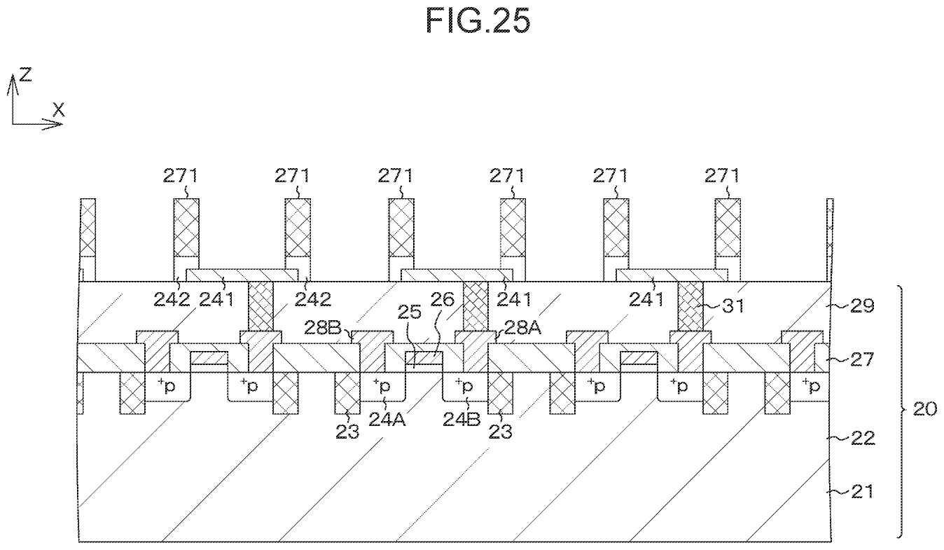

Next, form a mask 271 that covers a portion where the insulating layer 242 surrounding the outer edge of the lower electrode 241 is to be formed (see FIG. 24). Thereafter, perform etching to remove the insulating material layer 242A while leaving the portion of the insulating material layer 242A covered with the mask 271 (see FIG. 25). Subsequently, remove the mask 271.

Through the above steps, the outer edge of the lower electrode 241 may be covered with the insulating layer 242 after the lower electrode 241 is formed for each light emitting unit ELP.

Thereafter, form the organic layer 42 on the entire surface including the upper surface of the lower electrode 241. Next, form a conductive material layer constituting the upper electrode 43 on the organic layer 42.

Through the above steps, the stacked body LM in which the materials constituting the lower electrode 241, the organic layer 42, and the upper electrode 43 are sequentially stacked is formed on the substrate 20. The configuration of the stacked body LM is the same as that in FIG. 13 referred to in the first embodiment except that the outer edge of the lower electrode 241 is surrounded by the insulating layer 242. Thus, the drawing is omitted.

[Step-210]

Next, perform the same step as [Step-110] described in the first embodiment with the lower electrode 41 being replaced with the lower electrode 241 and the insulating layer 242 surrounding the outer edge of the lower electrode 241.

Through the above steps, the stacked body LM corresponding to the portion between the light emitting unit ELP and the light emitting unit ELP is removed, and the light emitting units ELP arranged in a matrix are formed. In addition, the groove GV having the bottom surface BT and the both side surfaces SL forming a gentle inclination angle with respect to the bottom surface BT is formed in the exposed portion of the substrate 20.

[Step-220]

Next, perform the same step as [Step-120] described in the first embodiment. The display apparatus 2 illustrated in FIG. 21 may be obtained by the above steps.

### Third Embodiment

A third embodiment also relates to the display apparatus, the display apparatus and the electronic device, and the method for manufacturing a display apparatus according to the present disclosure.

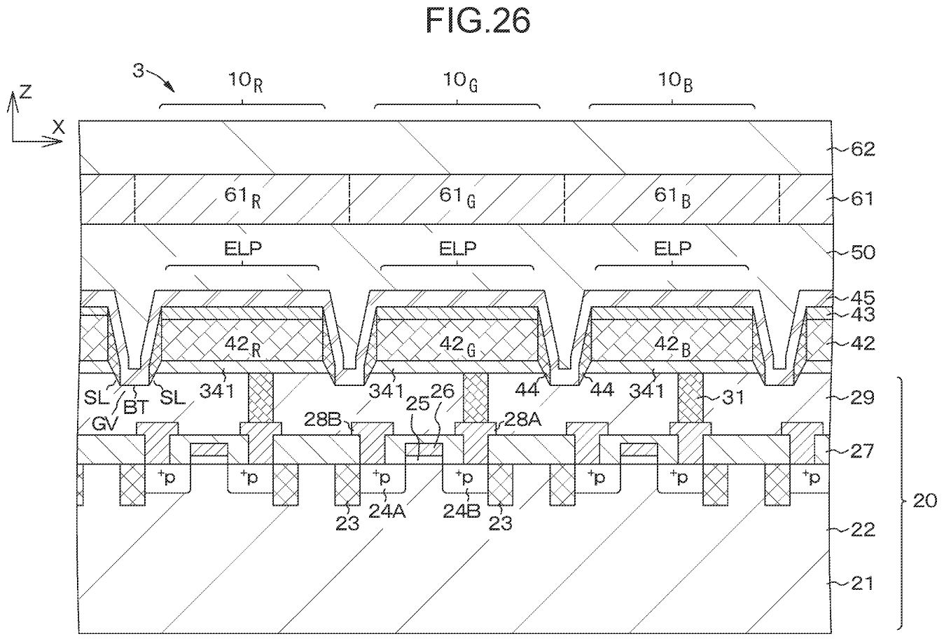

FIG. 26 is a schematic and partial sectional view of a substrate and the like for explaining a structure of a display apparatus according to the third embodiment, corresponding to FIG. 3 referred to in the first embodiment. In the schematic view of the display apparatus according to the third embodiment, the display apparatus 1 is replaced with a display apparatus 3 in FIG. 1.

Unlike the first embodiment and the second embodiment, a lower electrode 341 in the display apparatus 3 is formed such that the outer edge is exposed to a side wall surface of the organic layer 42. The above point is different from the display apparatus 1 described in the first embodiment.

In this configuration as well, the inclined surface SL of the groove GV is positioned at the periphery of the organic layer 42. As in the first embodiment, the deposited film 44 is formed on the side surface SL of the groove GV of the substrate. Thus, the entire side wall surface of the organic layer 42 is covered with the deposited film 44.

Next, a method for manufacturing the display apparatus 3 will be described. A method for manufacturing the display apparatus 3 includes, in the same manner as in the first embodiment:
a first step of forming a stacked body in which materials constituting the lower electrode, the organic layer, and the upper electrode are sequentially stacked on the substrate;
a second step of removing a part of the stacked body corresponding to a portion between adjacent light emitting units and thereafter further forming a groove in a part of the substrate being exposed, the groove having a bottom surface and both side surfaces forming a gentle inclination angle with respect to the bottom surface; and
a third step of forming a protective film in common on entire surface including an upper surface of the light emitting unit and an upper surface of the groove of the substrate.

In the first step, the stacked body in which materials constituting the organic layer and the upper electrode are sequentially stacked is formed. The lower electrode is formed for each light emitting unit by removing a part of the stacked body corresponding to a portion between adjacent light emitting units in the second step. Further, in the second step, the part of the stacked body corresponding to a portion between adjacent light emitting units is removed by an etching method, then a groove is further formed in a part of the substrate being exposed, the groove having a bottom surface and both side surfaces forming a gentle inclination angle with respect to the bottom surface, and at the same time a side wall surface of the organic layer is covered with a deposited film generated by etching processing.

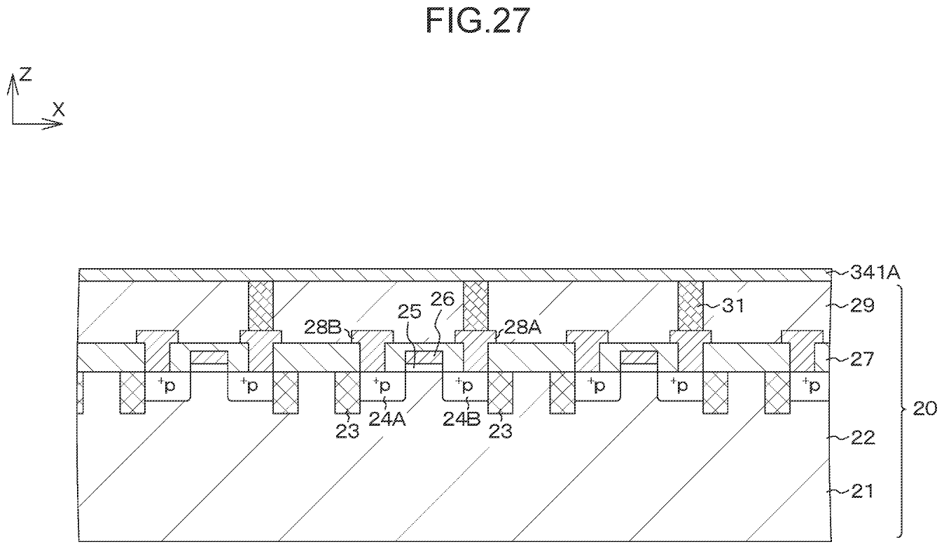

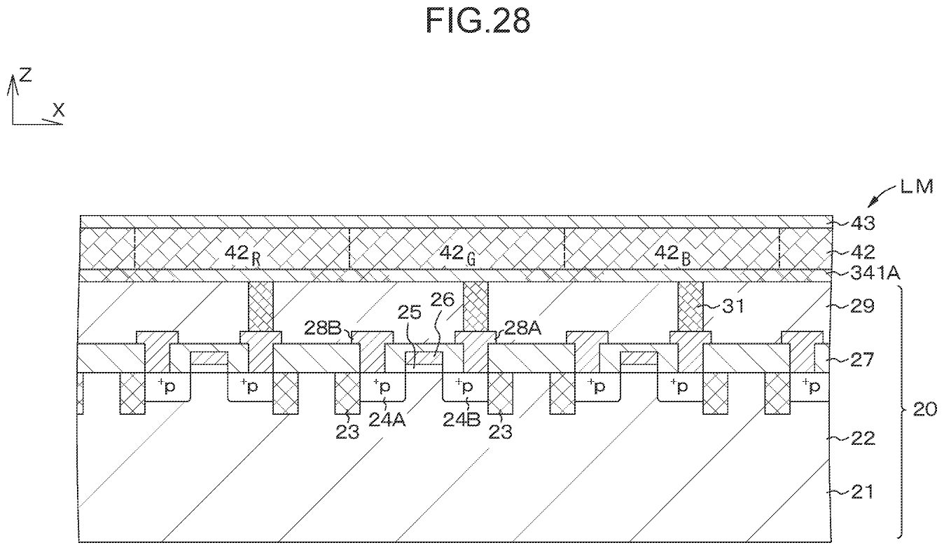

FIGS. 27 and 28 are schematic and partial sectional views of a substrate and the like for explaining the method for manufacturing the display apparatus according to the third embodiment. Hereinafter, the method for manufacturing the display apparatus 3 will be described in detail.

[Step-300] (See FIGS. 27 and 28)

First, prepare the base material 21 on which transistors are formed (see FIG. 12A of the first embodiment), and form the wiring layer 29 thereon by a well-known film forming method or patterning method.

Next, form the via 31 penetrating the wiring layer 29. Thereafter, form a material layer 341A constituting the lower electrode 341 on the wiring layer 29 in common for every light emitting unit ELP (see FIG. 27).

Next, form the organic layer 42 on the entire surface including the upper surface of the material layer 341A. Thereafter, form a conductive material layer (indicated by reference sign 43 for convenience) constituting the upper electrode 43 on the organic layer 42 (see FIG. 28).

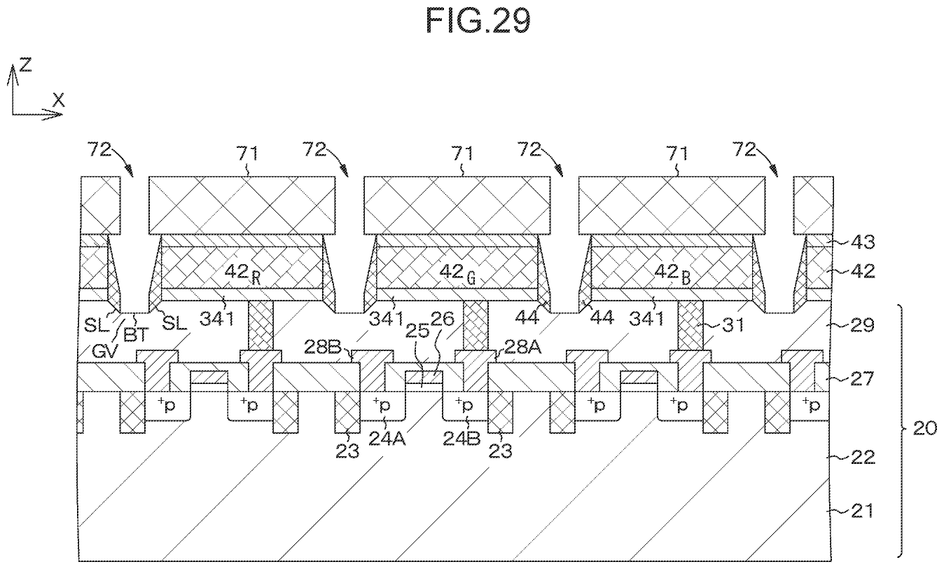

Through the above steps, the stacked body LM in which the materials constituting the material layer 341A, the organic layer 42, and the upper electrode 43 are sequentially stacked is formed on the substrate 20.

[Step-310] (see FIG. 29)

Next, perform the same step as [Step-110] described in the first embodiment. By removing the stacked body LM in the portion of the mask opening 72, the material layer 341A is divided to constitute the lower electrode 341, and the light emitting units ELP arranged in a matrix are formed. In addition, the groove GV having the bottom surface BT and the both side surfaces SL forming a gentle inclination angle with respect to the bottom surface BT is formed in the exposed portion of the substrate 20. In addition, since a byproduct generated through etching processing of the wiring layer 29 adheres to the periphery, the protective film 44 is formed on a side wall surface of the organic layer 42 (see FIG. 29). Thereafter, remove the mask 71.

[Step-320]

Next, perform the same step as [Step-120] described in the first embodiment. The display apparatus 3 illustrated in FIG. 26 may be obtained by the above steps.

As described above, in the method for manufacturing the display apparatus 3, the lower electrode 341 is formed by removing the stacked body LM corresponding to the portion between the light emitting unit ELP and the light emitting unit ELP. In the first embodiment and the second embodiment, it was necessary to form the lower electrode by patterning the lower electrode on the substrate in the first step. Since the lower electrode is formed in the second step, the method for manufacturing the display apparatus 3 has an advantage that the step can be simplified.

[Description of Electronic Device]

The display apparatus according to the present disclosure described above may be used as a display unit of an electronic device in any field that displays a video signal input to the electronic device or a video signal generated in the electronic device as an image or a video. As an example, the display apparatus may be used as a display unit of, for example, a television set, a digital still camera, a notebook personal computer, a mobile terminal device such as a mobile phone, a video camera, a head mounted display, or the like.

The display apparatus of the present disclosure also includes a module having a sealed configuration. The display module may be provided with a circuit unit for inputting and outputting signals and the like from the outside to a pixel array unit, a flexible printed circuit (FPC), and the like. Hereinafter, a digital still camera and a head mounted display will be exemplified as electronic devices including the display apparatus of the present disclosure. However, the specific examples described here are merely examples, and the present disclosure is not limited to the examples.

### Specific Example 1

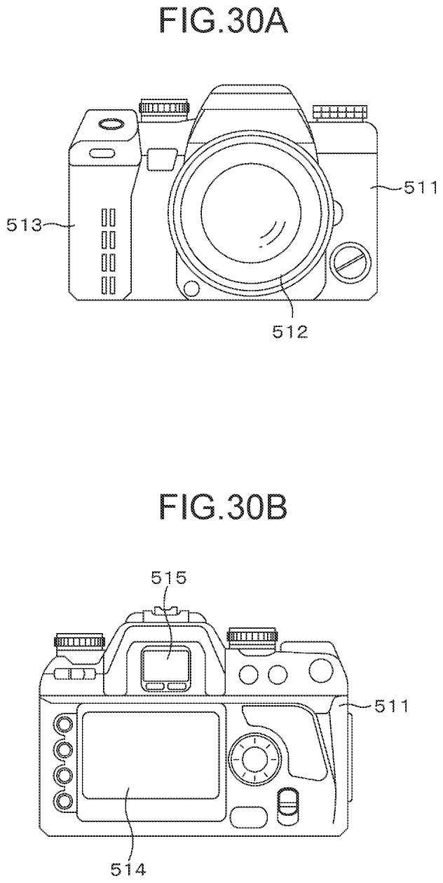

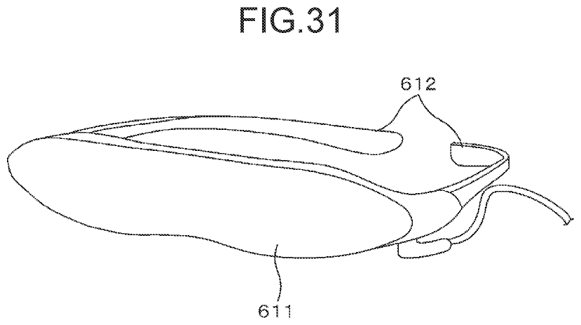

FIG. 30 is an external view of a lens interchangeable single-lens reflex digital still camera. FIG. 30A is a front view of the camera, and FIG. 30B is a back view of the camera. This lens interchangeable single-lens reflex digital still camera includes, for example, an interchangeable photographing lens unit (interchangeable lens) 512 on the front right side of a camera body 511, and a grip 513 to be held by a photographer on the front left side.

A monitor 514 is provided substantially at the center of the back surface of the camera body 511. A viewfinder (eyepiece window) 515 is provided above the monitor 514. The photographer can visually recognize an optical image of a subject guided from the photographing lens unit 512 and determine a composition by looking into the viewfinder 515.

The display apparatus of the present disclosure can be used as the viewfinder 515 in the lens interchangeable single-lens reflex digital still camera having such a configuration. That is, the lens interchangeable single-lens reflex digital still camera according to the present example is produced by using the display apparatus of the present disclosure as the viewfinder 515.

### Specific Example 2

FIG. 31 is an external view of a head mounted display. The head mounted display includes, for example, ear hooks 612 to be worn on the head of a user on both sides of an eyeglass-shaped display unit 611. The display apparatus of the present disclosure can be used as the display unit 611 in the head mounted display. That is, the head mounted display according to the present example is produced by using the display apparatus of the present disclosure as the display unit 611.

### Specific Example 3

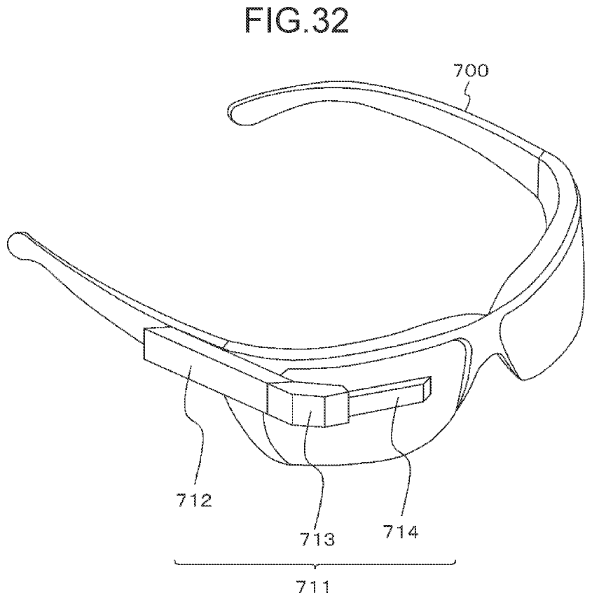

FIG. 32 is an external view of a see-through head mounted display. A see-through head mounted display 711 includes a main body 712, an arm 713, and a lens barrel 714.

The main body 712 is connected to the arm 713 and eyeglasses 700. Specifically, an end of the main body 712 in a long side direction is coupled to the arm 713, and one side surface of the main body 712 is coupled to the eyeglasses 700 via a connecting member. The main body 712 may be directly mounted on the head of a human body.

The main body 712 incorporates a control board for controlling the operation of the head mounted display 711 and a display unit. The arm 713 connects the main body 712 and the lens barrel 714 and supports the lens barrel 714. Specifically, the arm 713 is coupled to an end of the main body 712 and an end of the lens barrel 714 to fix the lens barrel 714. The arm 713 incorporates a signal line for communicating data related to an image provided from the main body 712 to the lens barrel 714.

The lens barrel 714 projects image light provided from the main body 712 via the arm 713 toward the eyes of a user wearing the see-through head mounted display 711 through eyepiece lenses. The display apparatus of the present disclosure can be used as the display unit of the main body 712 in the see-through head mounted display 711.

### Application Example 1

The technology according to the present disclosure can be applied to various products. For example, the technology according to the present disclosure may be realized as a device mounted on any type of mobile body such as an automobile, an electric vehicle, a hybrid electric vehicle, a motorcycle, a bicycle, a personal mobility, an airplane, a drone, a vessel, a robot, a construction machine, or an agricultural machine (tractor).

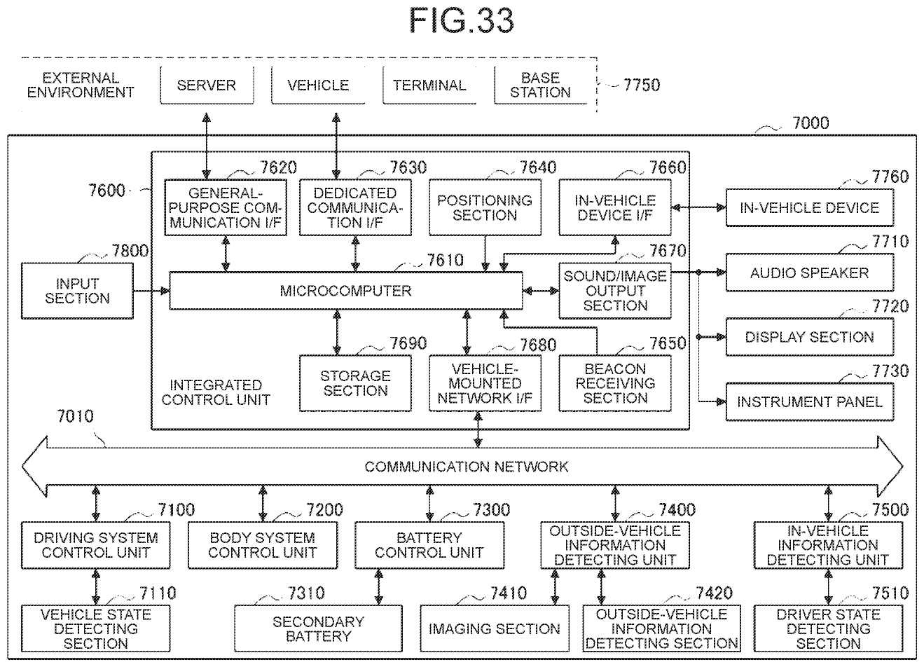

FIG. 33 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 33, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 33 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

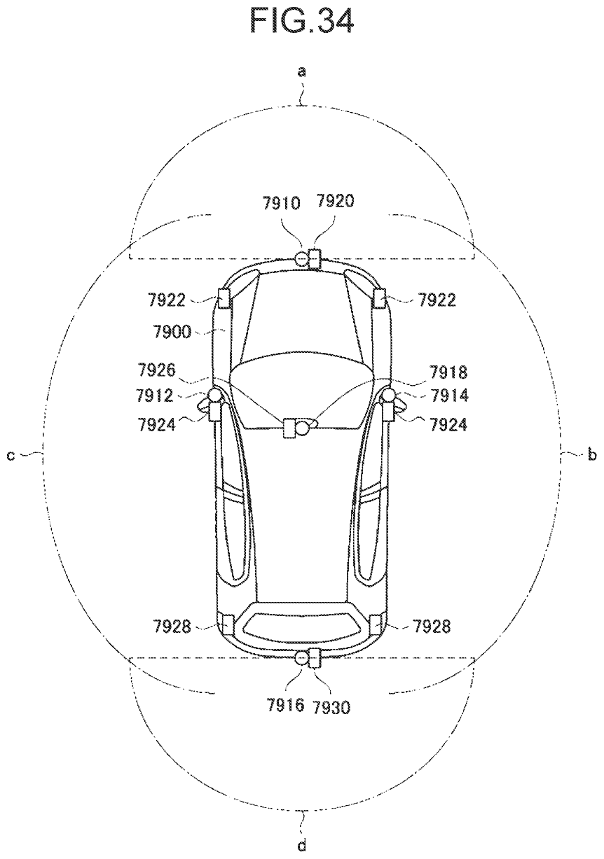

FIG. 34 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 34 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 33, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access WiMAX, long term evolution (LTE), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 33, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 33 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

The technology according to the present disclosure may be applied to, for example, a display unit of an output device capable of visually or aurally notifying information among the above-described configurations.

### Application Example 2

The technology according to the present disclosure can be applied to various products. For example, the technology according to the present disclosure may be applied to a surgery room system.

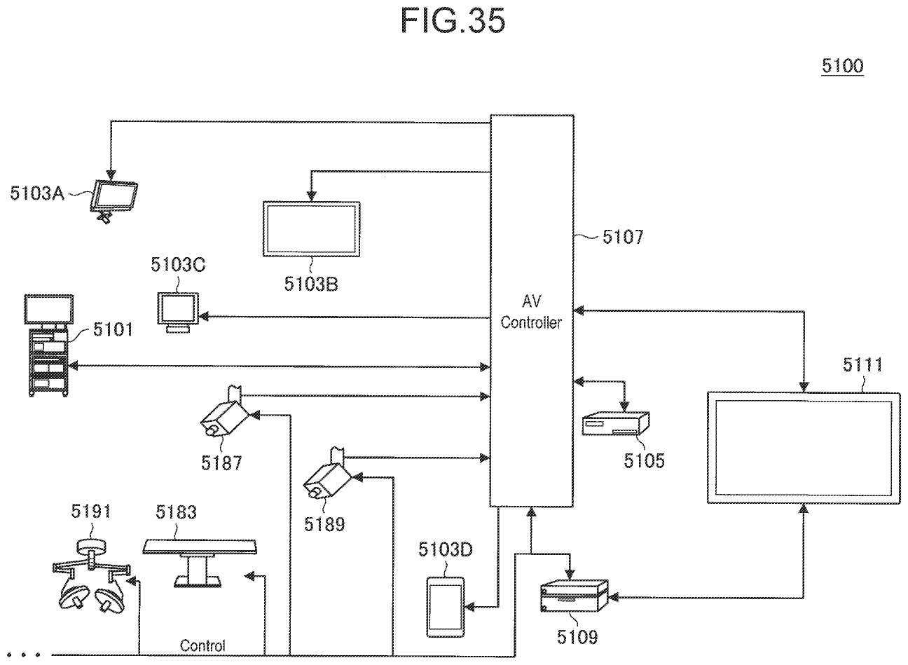

FIG. 35 is a view schematically depicting a general configuration of a surgery room system 5100 to which the technology according to an embodiment of the present disclosure can be applied. Referring to FIG. 35, the surgery room system 5100 is configured such that a group of apparatus installed in a surgery room are connected for cooperation with each other through an audiovisual (AV) controller 5107 and a surgery room controlling apparatus 5109.

In the surgery room, various apparatus may be installed. In FIG. 35, as an example, various apparatus group 5101 for endoscopic surgery, a ceiling camera 5187, a surgery field camera 5189, a plurality of display apparatus 5103A to 5103D, a recorder 5105, a patient bed 5183 and an illumination 5191 are depicted. The ceiling camera 5187 is provided on the ceiling of a surgery room and images the hands of a surgeon. The surgery field camera 5189 is provided on the ceiling of the surgery room and images a state of the entire surgery room.

Among the apparatus mentioned, the apparatus group 5101 belongs to an endoscopic surgery system 5113 hereinafter described and include an endoscope, a display apparatus which displays an image picked up by the endoscope and so forth. Various apparatus belonging to the endoscopic surgery system 5113 are referred to also as medical equipment. Meanwhile, the display apparatus 5103A to 5103D, the recorder 5105, the patient bed 5183 and the illumination 5191 are apparatus which are equipped, for example, in the surgery room separately from the endoscopic surgery system 5113. The apparatus which do not belong to the endoscopic surgery system 5113 are referred to also as non-medical equipment. The audiovisual controller 5107 and/or the surgery room controlling apparatus 5109 cooperatively control operation of the medical equipment and the non-medical equipment with each other.

The audiovisual controller 5107 integrally controls processes of the medical equipment and the non-medical equipment relating to image display. Specifically, each of the apparatus group 5101, the ceiling camera 5187 and the surgery field camera 5189 from among the apparatus provided in the surgery room system 5100 may be an apparatus having a function of sending information to be displayed during surgery (such information is hereinafter referred to as display information, and the apparatus mentioned is hereinafter referred to as apparatus of a sending source). Meanwhile, each of the display apparatus 5103A to 5103D may be an apparatus to which display information is outputted (the apparatus is hereinafter referred to also as apparatus of an output destination). Further, the recorder 5105 may be an apparatus which serves as both of an apparatus of a sending source and an apparatus of an output destination. The audiovisual controller 5107 has a function of controlling operation of an apparatus of a sending source and an apparatus of an output destination to acquire display information from the apparatus of a sending source and transmit the display information to the apparatus of an output destination so as to be displayed or recorded. It is to be noted that the display information includes various images picked up during surgery, various kinds of information relating to the surgery (for example, physical information of a patient, inspection results in the past or information regarding a surgical procedure) and so forth.

Specifically, to the audiovisual controller 5107, information relating to an image of a surgical region in a body lumen of a patient imaged by the endoscope may be transmitted as the display information from the apparatus group 5101. Further, from the ceiling camera 5187, information relating to an image of the hands of the surgeon picked up by the ceiling camera 5187 may be transmitted as display information. Further, from the surgery field camera 5189, information relating to an image picked up by the surgery field camera 5189 and illustrating a state of the entire surgery room may be transmitted as display information. It is to be noted that, if a different apparatus having an image pickup function exists in the surgery room system 5100, then the audiovisual controller 5107 may acquire information relating to an image picked up by the different apparatus as display information also from the different apparatus.

Alternatively, for example, in the recorder 5105, information relating to such images as mentioned above picked up in the past is recorded by the audiovisual controller 5107. The audiovisual controller 5107 can acquire, as display information, information relating to the images picked up in the past from the recorder 5105. It is to be noted that also various pieces of information relating to surgery may be recorded in advance in the recorder 5105.

The audiovisual controller 5107 controls at least one of the display apparatus 5103A to 5103D, which are apparatus of an output destination, to display acquired display information (namely, images picked up during surgery or various pieces of information relating to the surgery). In the example depicted, the display apparatus 5103A is a display apparatus installed so as to be suspended from the ceiling of the surgery room; the display apparatus 5103B is a display apparatus installed on a wall face of the surgery room; the display apparatus 5103C is a display apparatus installed on a desk in the surgery room; and the display apparatus 5103D is a mobile apparatus (for example, a tablet personal computer (PC)) having a display function.

Further, though not depicted in FIG. 35, the surgery room system 5100 may include an apparatus outside the surgery room. The apparatus outside the surgery room may be, for example, a server connected to a network constructed inside and outside the hospital, a PC used by medical staff, a projector installed in a meeting room of the hospital or the like. Where such an external apparatus is located outside the hospital, also it is possible for the audiovisual controller 5107 to cause display information to be displayed on a display apparatus of a different hospital through a teleconferencing system or the like to perform telemedicine.

The surgery room controlling apparatus 5109 integrally controls processes other than processes relating to image display on the non-medical equipment. For example, the surgery room controlling apparatus 5109 controls driving of the patient bed 5183, the ceiling camera 5187, the surgery field camera 5189 and the illumination 5191.

In the surgery room system 5100, a centralized operation panel 5111 is provided such that it is possible to issue an instruction regarding image display to the audiovisual controller 5107 or issue an instruction regarding operation of the non-medical equipment to the surgery room controlling apparatus 5109 through the centralized operation panel 5111. The centralized operation panel 5111 is configured by providing a touch panel on a display face of a display apparatus.

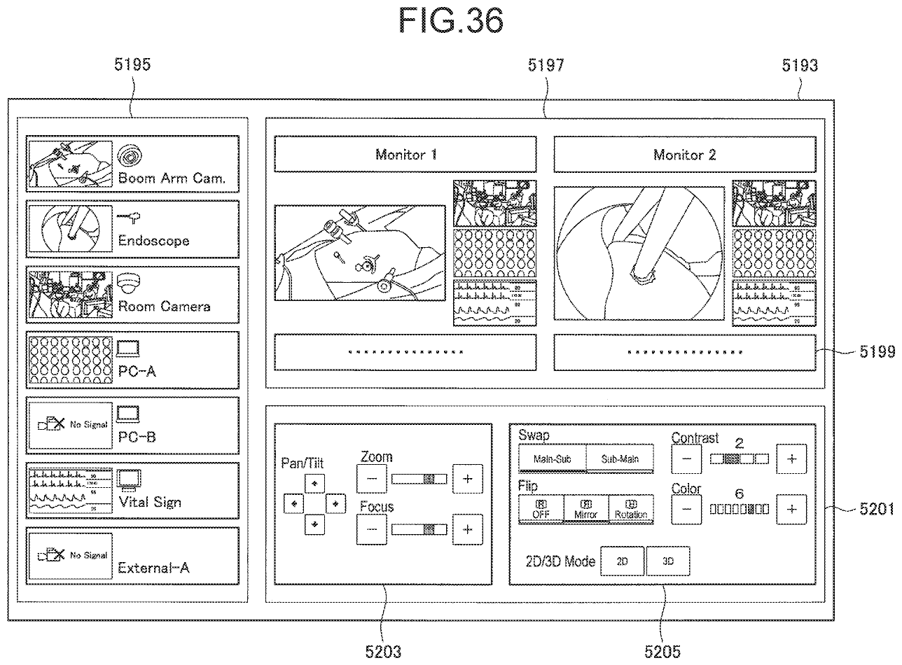

FIG. 36 is a view depicting an example of display of an operation screen image on the centralized operation panel 5111. In FIG. 36, as an example, an operation screen image is depicted which corresponds to a case in which two display apparatus are provided as apparatus of an output destination in the surgery room system 5100. Referring to FIG. 36, the operation screen image 5193 includes a sending source selection region 5195, a preview region 5197 and a control region 5201.

In the sending source selection region 5195, the sending source apparatus provided in the surgery room system 5100 and thumbnail screen images representative of display information the sending source apparatus have are displayed in an associated manner with each other. A user can select display information to be displayed on the display apparatus from any of the sending source apparatus displayed in the sending source selection region 5195.

In the preview region 5197, a preview of screen images displayed on two display apparatus (Monitor 1 and Monitor 2) which are apparatus of an output destination is displayed. In the example depicted, four images are displayed by picture in picture (PinP) display in regard to one display apparatus. The four images correspond to display information sent from the sending source apparatus selected in the sending source selection region 5195. One of the four images is displayed in a comparatively large size as a main image while the remaining three images are displayed in a comparatively small size as sub images. The user can exchange between the main image and the sub images by suitably selecting one of the images from among the four images displayed in the region. Further, a status displaying region 5199 is provided below the region in which the four images are displayed, and a status relating to surgery (for example, elapsed time of the surgery, physical information of the patient and so forth) may be displayed suitably in the status displaying region 5199.

A sending source operation region 5203 and an output destination operation region 5205 are provided in the control region 5201. In the sending source operation region 5203, a graphical user interface (GUI) part for performing an operation for an apparatus of a sending source is displayed. In the output destination operation region 5205, a GUI part for performing an operation for an apparatus of an output destination is displayed. In the example depicted, GUI parts for performing various operations for a camera (panning, tilting and zooming) in an apparatus of a sending source having an image pickup function are provided in the sending source operation region 5203. The user can control operation of the camera of an apparatus of a sending source by suitably selecting any of the GUI parts. It is to be noted that, though not depicted, where the apparatus of a sending source selected in the sending source selection region 5195 is a recorder (namely, where an image recorded in the recorder in the past is displayed in the preview region 5197), GUI parts for performing such operations as reproduction of the image, stopping of reproduction, rewinding, fast-feeding and so forth may be provided in the sending source operation region 5203.

Further, in the output destination operation region 5205, GUI parts for performing various operations for display on a display apparatus which is an apparatus of an output destination (swap, flip, color adjustment, contrast adjustment and switching between two dimensional (2D) display and three dimensional (3D) display) are provided. The user can operate the display of the display apparatus by suitably selecting any of the GUI parts.

It is to be noted that the operation screen image to be displayed on the centralized operation panel 5111 is not limited to the depicted example, and the user may be able to perform operation inputting to each apparatus which can be controlled by the audiovisual controller 5107 and the surgery room controlling apparatus 5109 provided in the surgery room system 5100 through the centralized operation panel 5111.

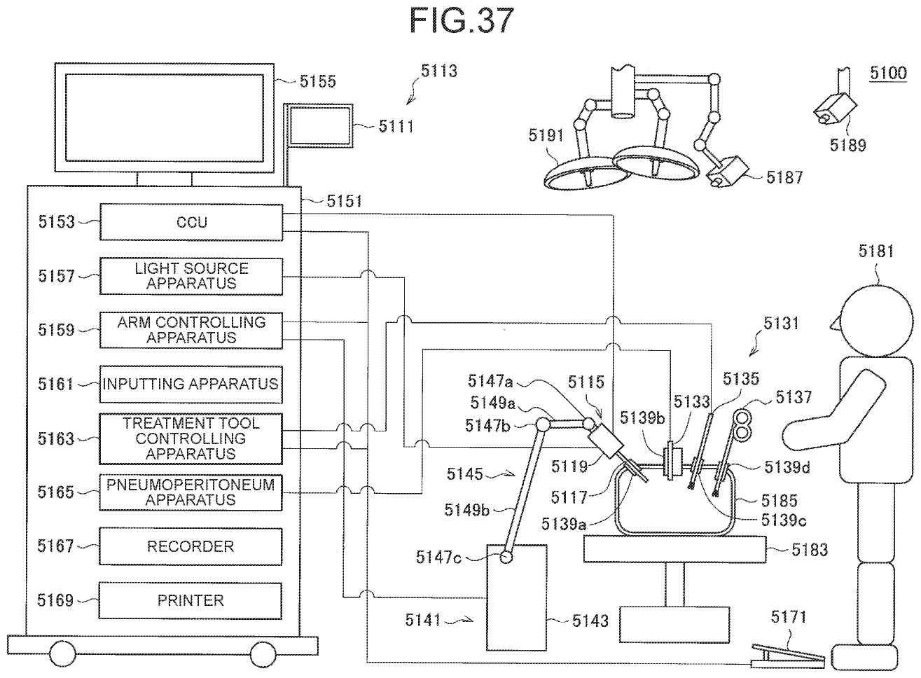

FIG. 37 is a view illustrating an example of a state of surgery to which the surgery room system described above is applied. The ceiling camera 5187 and the surgery field camera 5189 are provided on the ceiling of the surgery room such that it can image the hands of a surgeon (medical doctor) 5181 who performs treatment for an affected area of a patient 5185 on the patient bed 5183 and the entire surgery room. The ceiling camera 5187 and the surgery field camera 5189 may include a magnification adjustment function, a focal distance adjustment function, an imaging direction adjustment function and so forth. The illumination 5191 is provided on the ceiling of the surgery room and irradiates at least upon the hands of the surgeon 5181. The illumination 5191 may be configured such that the irradiation light amount, the wavelength (color) of the irradiation light, the irradiation direction of the light and so forth can be adjusted suitably.

The endoscopic surgery system 5113, the patient bed 5183, the ceiling camera 5187, the surgery field camera 5189 and the illumination 5191 are connected for cooperation with each other through the audiovisual controller 5107 and the surgery room controlling apparatus 5109 (not depicted in FIG. 37) as depicted in FIG. 35. The centralized operation panel 5111 is provided in the surgery room, and the user can suitably operate the apparatus existing in the surgery room through the centralized operation panel 5111 as described hereinabove.

In the following, a configuration of the endoscopic surgery system 5113 is described in detail. As depicted, the endoscopic surgery system 5113 includes an endoscope 5115, other surgical tools 5131, a supporting arm apparatus 5141 which supports the endoscope 5115 thereon, and a cart 5151 on which various apparatus for endoscopic surgery are mounted.

In endoscopic surgery, in place of incision of the abdominal wall to perform laparotomy, a plurality of tubular aperture devices called trocars 5139a to 5139d are used to puncture the abdominal wall. Then, a lens barrel 5117 of the endoscope 5115 and the other surgical tools 5131 are inserted into body lumens of the patient 5185 through the trocars 5139a to 5139d. In the example depicted, as the other surgical tools 5131, a pneumoperitoneum tube 5133, an energy treatment tool 5135 and forceps 5137 are inserted into body lumens of the patient 5185. Further, the energy treatment tool 5135 is a treatment tool for performing incision and peeling of a tissue, sealing of a blood vessel or the like by high frequency current or ultrasonic vibration. However, the surgical tools 5131 depicted are mere examples at all, and as the surgical tools 5131, various surgical tools which are generally used in endoscopic surgery such as, for example, a pair of tweezers or a retractor may be used.

An image of a surgical region in a body lumen of the patient 5185 picked up by the endoscope 5115 is displayed on a display apparatus 5155. The surgeon 5181 would use the energy treatment tool 5135 or the forceps 5137 while watching the image of the surgical region displayed on the display apparatus 5155 on the real time basis to perform such treatment as, for example, resection of an affected area. It is to be noted that, though not depicted, the pneumoperitoneum tube 5133, the energy treatment tool 5135, and the forceps 5137 are supported by the surgeon 5181, an assistant or the like during surgery.

(Supporting Arm Apparatus)

The supporting arm apparatus 5141 includes an arm unit 5145 extending from a base unit 5143. In the example depicted, the arm unit 5145 includes joint portions 5147a, 5147b and 5147c and links 5149a and 5149b and is driven under the control of an arm controlling apparatus 5159. The endoscope 5115 is supported by the arm unit 5145 such that the position and the posture of the endoscope 5115 are controlled. Consequently, stable fixation in position of the endoscope 5115 can be implemented.

(Endoscope)

The endoscope 5115 includes the lens barrel 5117 which has a region of a predetermined length from a distal end thereof to be inserted into a body lumen of the patient 5185, and a camera head 5119 connected to a proximal end of the lens barrel 5117. In the example depicted, the endoscope 5115 is depicted which is configured as a hard mirror having the lens barrel 5117 of the hard type. However, the endoscope 5115 may otherwise be configured as a soft mirror having the lens barrel 5117 of the soft type.

The lens barrel 5117 has, at a distal end thereof, an opening in which an objective lens is fitted. A light source apparatus 5157 is connected to the endoscope 5115 such that light generated by the light source apparatus 5157 is introduced to a distal end of the lens barrel 5117 by a light guide extending in the inside of the lens barrel 5117 and is applied toward an observation target in a body lumen of the patient 5185 through the objective lens. It is to be noted that the endoscope 5115 may be a direct view mirror or may be a perspective view mirror or a side view mirror.

An optical system and an image pickup element are provided in the inside of the camera head 5119 such that reflected light (observation light) from an observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 5153. It is to be noted that the camera head 5119 has a function incorporated therein for suitably driving the optical system of the camera head 5119 to adjust the magnification and the focal distance.

It is to be noted that, in order to establish compatibility with, for example, a stereoscopic vision (3D display), a plurality of image pickup elements may be provided on the camera head 5119. In this case, a plurality of relay optical systems are provided in the inside of the lens barrel 5117 in order to guide observation light to the plurality of respective image pickup elements.

(Various Apparatus Incorporated in Cart)

The CCU 5153 includes a central processing unit (CPU), a graphics processing unit (GPU) or the like and integrally controls operation of the endoscope 5115 and the display apparatus 5155. Specifically, the CCU 5153 performs, for an image signal received from the camera head 5119, various image processes for displaying an image based on the image signal such as, for example, a development process (demosaic process). The CCU 5153 provides the image signal for which the image processes have been performed to the display apparatus 5155. Further, the audiovisual controller 5107 depicted in FIG. 35 is connected to the CCU 5153. The CCU 5153 provides the image signal for which the image processes have been performed also to the audiovisual controller 5107. Further, the CCU 5153 transmits a control signal to the camera head 5119 to control driving of the camera head 5119. The control signal may include information relating to an image pickup condition such as a magnification or a focal distance. The information relating to an image pickup condition may be inputted through the inputting apparatus 5161 or may be inputted through the centralized operation panel 5111 described hereinabove.

The display apparatus 5155 displays an image based on an image signal for which the image processes have been performed by the CCU 5153 under the control of the CCU 5153. If the endoscope 5115 is ready for imaging of a high resolution such as 4K (horizontal pixel number 3840×vertical pixel number 2160), 8K (horizontal pixel number 7680×vertical pixel number 4320) or the like and/or ready for 3D display, then a display apparatus by which corresponding display of the high resolution and/or 3D display are possible may be used as the display apparatus 5155. Where the apparatus is ready for imaging of a high resolution such as 4K or 8K, if the display apparatus used as the display apparatus 5155 has a size of equal to or not less than 55 inches, then a more immersive experience can be obtained. Further, a plurality of display apparatus 5155 having different resolutions and/or different sizes may be provided in accordance with purposes.

The light source apparatus 5157 includes a light source such as, for example, a light emitting diode (LED) and supplies irradiation light for imaging of a surgical region to the endoscope 5115.

The arm controlling apparatus 5159 includes a processor such as, for example, a CPU and operates in accordance with a predetermined program to control driving of the arm unit 5145 of the supporting arm apparatus 5141 in accordance with a predetermined controlling method.

An inputting apparatus 5161 is an input interface for the endoscopic surgery system 5113. A user can perform inputting of various kinds of information or instruction inputting to the endoscopic surgery system 5113 through the inputting apparatus 5161. For example, the user would input various kinds of information relating to surgery such as physical information of a patient, information regarding a surgical procedure of the surgery and so forth through the inputting apparatus 5161. Further, the user would input, for example, an instruction to drive the arm unit 5145, an instruction to change an image pickup condition (type of irradiation light, magnification, focal distance or the like) by the endoscope 5115, an instruction to drive the energy treatment tool 5135 or a like through the inputting apparatus 5161.

The type of the inputting apparatus 5161 is not limited and may be that of any one of various known inputting apparatus. As the inputting apparatus 5161, for example, a mouse, a keyboard, a touch panel, a switch, a foot switch 5171 and/or a lever or the like may be applied. Where a touch panel is used as the inputting apparatus 5161, it may be provided on the display face of the display apparatus 5155.

The inputting apparatus 5161 is otherwise a device to be mounted on a user such as, for example, a glasses type wearable device or a head mounted display (HMD), and various kinds of inputting are performed in response to a gesture or a line of sight of the user detected by any of the devices mentioned. Further, the inputting apparatus 5161 includes a camera which can detect a motion of a user, and various kinds of inputting are performed in response to a gesture or a line of sight of a user detected from a video picked up by the camera. Further, the inputting apparatus 5161 includes a microphone which can collect the voice of a user, and various kinds of inputting are performed by voice through the microphone. By configuring the inputting apparatus 5161 such that various kinds of information can be inputted in a contactless fashion in this manner, especially a user who belongs to a clean area (for example, the surgeon 5181) can operate an apparatus belonging to an unclean area in a contactless fashion. Further, since the user can operate an apparatus without releasing a possessed surgical tool from its hand, the convenience to the user is improved.

A treatment tool controlling apparatus 5163 controls driving of the energy treatment tool 5135 for cautery or incision of a tissue, sealing of a blood vessel or the like. A pneumoperitoneum apparatus 5165 feeds gas into a body lumen of the patient 5185 through the pneumoperitoneum tube 5133 to inflate the body lumen in order to secure the field of view of the endoscope 5115 and secure the working space for the surgeon. A recorder 5167 is an apparatus capable of recording various kinds of information relating to surgery. A printer 5169 is an apparatus capable of printing various kinds of information relating to surgery in various forms such as a text, an image or a graph.

In the following, especially a characteristic configuration of the endoscopic surgery system 5113 is described in more detail.

(Supporting Arm Apparatus)

The supporting arm apparatus 5141 includes the base unit 5143 serving as a base, and the arm unit 5145 extending from the base unit 5143. In the example depicted, the arm unit 5145 includes the plurality of joint portions 5147a, 5147b and 5147c and the plurality of links 5149a and 5149b connected to each other by the joint portion 5147b. In FIG. 37, for simplified illustration, the configuration of the arm unit 5145 is depicted in a simplified form. Actually, the shape, number and arrangement of the joint portions 5147a to 5147c and the links 5149a and 5149b and the direction and so forth of axes of rotation of the joint portions 5147a to 5147c can be set suitably such that the arm unit 5145 has a desired degree of freedom. For example, the arm unit 5145 may preferably be included such that it has a degree of freedom equal to or not less than 6 degrees of freedom. This makes it possible to move the endoscope 5115 freely within the movable range of the arm unit 5145. Consequently, it becomes possible to insert the lens barrel 5117 of the endoscope 5115 from a desired direction into a body lumen of the patient 5185.

An actuator is provided in the joint portions 5147a to 5147c, and the joint portions 5147a to 5147c include such that they are rotatable around predetermined axes of rotation thereof by driving of the actuator. The driving of the actuator is controlled by the arm controlling apparatus 5159 to control the rotational angle of each of the joint portions 5147a to 5147c thereby to control driving of the arm unit 5145. Consequently, control of the position and the posture of the endoscope 5115 can be implemented. Thereupon, the arm controlling apparatus 5159 can control driving of the arm unit 5145 by various known controlling methods such as force control or position control.

For example, if the surgeon 5181 suitably performs operation inputting through the inputting apparatus 5161 (including the foot switch 5171), then driving of the arm unit 5145 may be controlled suitably by the arm controlling apparatus 5159 in response to the operation input to control the position and the posture of the endoscope 5115. After the endoscope 5115 at the distal end of the arm unit 5145 is moved from an arbitrary position to a different arbitrary position by the control just described, the endoscope 5115 can be supported fixedly at the position after the movement. It is to be noted that the arm unit 5145 may be operated in a master-slave fashion. In this case, the arm unit 5145 may be remotely controlled by the user through the inputting apparatus 5161 which is placed at a place remote from the surgery room.

Further, where force control is applied, the arm controlling apparatus 5159 may perform power-assisted control to drive the actuators of the joint portions 5147a to 5147c such that the arm unit 5145 may receive external force by the user and move smoothly following the external force. This makes it possible to move the arm unit 5145 with comparatively weak force when the user directly touches with and moves the arm unit 5145. Accordingly, it becomes possible for the user to move the endoscope 5115 more intuitively by a simpler and easier operation, and the convenience to the user can be improved.

Here, generally in endoscopic surgery, the endoscope 5115 is supported by a medical doctor called scopist. In contrast, where the supporting arm apparatus 5141 is used, the position of the endoscope 5115 can be fixed with a higher degree of certainty without hands, and therefore, an image of a surgical region can be obtained stably and surgery can be performed smoothly.

It is to be noted that the arm controlling apparatus 5159 may not necessarily be provided on the cart 5151. Further, the arm controlling apparatus 5159 may not necessarily be a single apparatus. For example, the arm controlling apparatus 5159 may be provided in each of the joint portions 5147a to 5147c of the arm unit 5145 of the supporting arm apparatus 5141 such that the plurality of arm controlling apparatus 5159 cooperate with each other to implement driving control of the arm unit 5145.

(Light Source Apparatus)

The light source apparatus 5157 supplies irradiation light upon imaging of a surgical region to the endoscope 5115. The light source apparatus 5157 includes a white light source which includes, for example, an LED, a laser light source or a combination of them. In this case, where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 5157. Further, in this case, if laser beams from the RGB laser light sources are applied time-divisionally on an observation target and driving of the image pickup elements of the camera head 5119 is controlled in synchronism with the irradiation timings, then images individually corresponding to the R, G and B colors can be picked up time-divisionally. According to the method just described, a color image can be obtained even if a color filter is not provided for the image pickup element.

Further, driving of the light source apparatus 5157 may be controlled such that the intensity of light to be outputted is changed for each predetermined time. By controlling driving of the image pickup element of the camera head 5119 in synchronism with the timing of the change of the intensity of light to acquire images time-divisionally and synthesizing the images, an image of a high dynamic range free from underexposed blocked up shadows and overexposed highlights can be created.

Further, the light source apparatus 5157 may be configured to supply light of a predetermined wavelength band ready for special light observation. In special light observation, for example, by utilizing the wavelength dependency of absorption of light of a body tissue, narrow band light observation (narrow band imaging) of imaging a predetermined tissue such as a blood vessel of a superficial portion of the mucous membrane or the like in a high contrast is performed by applying light of a narrower band in comparison with irradiation light upon ordinary observation (namely, white light). Alternatively, in special light observation, fluorescent observation for obtaining an image from fluorescent light generated by irradiation of excitation light may also be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 5157 can be configured to supply such narrow-band light and/or excitation light suitable for special light observation as described above.

(Camera Head and CCU)

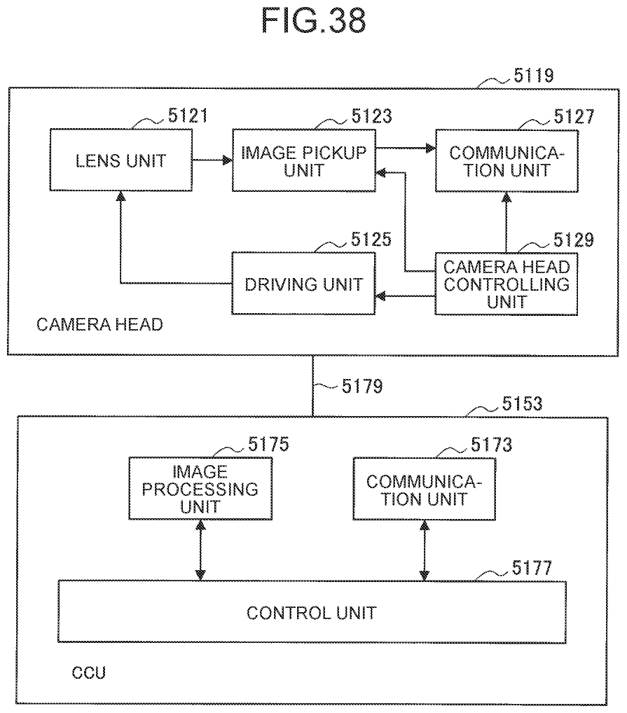

Functions of the camera head 5119 of the endoscope 5115 and the CCU 5153 are described in more detail with reference to FIG. 38. FIG. 38 is a block diagram depicting an example of a functional configuration of the camera head 5119 and the CCU 5153 depicted in FIG. 37.

Referring to FIG. 38, the camera head 5119 has, as functions thereof, a lens unit 5121, an image pickup unit 5123, a driving unit 5125, a communication unit 5127 and a camera head controlling unit 5129. Further, the CCU 5153 has, as functions thereof, a communication unit 5173, an image processing unit 5175 and a control unit 5177. The camera head 5119 and the CCU 5153 are connected to be bidirectionally communicable to each other by a transmission cable 5179.

First, a functional configuration of the camera head 5119 is described. The lens unit 5121 is an optical system provided at a connecting location of the camera head 5119 to the lens barrel 5117. Observation light taken in from a distal end of the lens barrel 5117 is introduced into the camera head 5119 and enters the lens unit 5121. The lens unit 5121 includes a combination of a plurality of lenses including a zoom lens and a focusing lens. The lens unit 5121 has optical properties adjusted such that the observation light is condensed on a light receiving face of the image pickup element of the image pickup unit 5123. Further, the zoom lens and the focusing lens include such that the positions thereof on their optical axis are movable for adjustment of the magnification and the focal point of a picked up image.

The image pickup unit 5123 includes an image pickup element and disposed at a succeeding stage to the lens unit 5121. Observation light having passed through the lens unit 5121 is condensed on the light receiving face of the image pickup element, and an image signal corresponding to the observation image is generated by photoelectric conversion. The image signal generated by the image pickup unit 5123 is provided to the communication unit 5127.

As the image pickup element which is included by the image pickup unit 5123, an image sensor, for example, of the complementary metal oxide semiconductor (CMOS) type is used which has a Bayer array and is capable of picking up an image in color. It is to be noted that, as the image pickup element, an image pickup element may be used which is ready, for example, for imaging of an image of a high resolution equal to or not less than 4K. If an image of a surgical region is obtained in a high resolution, then the surgeon 5181 can comprehend a state of the surgical region in enhanced details and can proceed with the surgery more smoothly.

Further, the image pickup element which is included by the image pickup unit 5123 is configured such that it has a pair of image pickup elements for acquiring image signals for the right eye and the left eye compatible with 3D display. Where 3D display is applied, the surgeon 5181 can comprehend the depth of a living body tissue in the surgical region with a higher degree of accuracy. It is to be noted that, if the image pickup unit 5123 is configured as that of the multi-plate type, then a plurality of systems of lens units 5121 are provided corresponding to the individual image pickup elements of the image pickup unit 5123.

The image pickup unit 5123 may not necessarily be provided on the camera head 5119. For example, the image pickup unit 5123 may be provided just behind the objective lens in the inside of the lens barrel 5117.

The driving unit 5125 includes an actuator and moves the zoom lens and the focusing lens of the lens unit 5121 by a predetermined distance along the optical axis under the control of the camera head controlling unit 5129. Consequently, the magnification and the focal point of a picked up image by the image pickup unit 5123 can be adjusted suitably.

The communication unit 5127 includes a communication apparatus for transmitting and receiving various kinds of information to and from the CCU 5153. The communication unit 5127 transmits an image signal acquired from the image pickup unit 5123 as RAW data to the CCU 5153 through the transmission cable 5179. Thereupon, in order to display a picked up image of a surgical region in low latency, preferably the image signal is transmitted by optical communication. This is because, since, upon surgery, the surgeon 5181 performs surgery while observing the state of an affected area through a picked up image, in order to achieve surgery with a higher degree of safety and certainty, it is demanded for a moving image of the surgical region to be displayed on the real time basis as far as possible. Where optical communication is applied, a photoelectric conversion module for converting an electric signal into an optical signal is provided in the communication unit 5127. After the image signal is converted into an optical signal by the photoelectric conversion module, it is transmitted to the CCU 5153 through the transmission cable 5179.

Further, the communication unit 5127 receives a control signal for controlling driving of the camera head 5119 from the CCU 5153. The control signal includes information relating to image pickup conditions such as, for example, information that a frame rate of a picked up image is designated, information that an exposure value upon image picking up is designated and/or information that a magnification and a focal point of a picked up image are designated. The communication unit 5127 provides the received control signal to the camera head controlling unit 5129. It is to be noted that also the control signal from the CCU 5153 may be transmitted by optical communication. In this case, a photoelectric conversion module for converting an optical signal into an electric signal is provided in the communication unit 5127. After the control signal is converted into an electric signal by the photoelectric conversion module, it is provided to the camera head controlling unit 5129.

It is to be noted that the image pickup conditions such as the frame rate, exposure value, magnification or focal point are set automatically by the control unit 5177 of the CCU 5153 on the basis of an acquired image signal. In other words, an auto exposure (AE) function, an auto focus (AF) function and an auto white balance (AWB) function are incorporated in the endoscope 5115.

The camera head controlling unit 5129 controls driving of the camera head 5119 on the basis of a control signal from the CCU 5153 received through the communication unit 5127. For example, the camera head controlling unit 5129 controls driving of the image pickup element of the image pickup unit 5123 on the basis of information that a frame rate of a picked up image is designated and/or information that an exposure value upon image picking up is designated. Further, for example, the camera head controlling unit 5129 controls the driving unit 5125 to suitably move the zoom lens and the focus lens of the lens unit 5121 on the basis of information that a magnification and a focal point of a picked up image are designated. The camera head controlling unit 5129 may include a function for storing information for identifying of the lens barrel 5117 and/or the camera head 5119.

It is to be noted that, by disposing the components such as the lens unit 5121 and the image pickup unit 5123 in a sealed structure having high airtightness and high waterproof, the camera head 5119 can be provided with resistance to an autoclave sterilization process.

Now, a functional configuration of the CCU 5153 is described. The communication unit 5173 includes a communication apparatus for transmitting and receiving various kinds of information to and from the camera head 5119. The communication unit 5173 receives an image signal transmitted thereto from the camera head 5119 through the transmission cable 5179. Thereupon, the image signal may be transmitted preferably by optical communication as described above. In this case, for the compatibility with optical communication, the communication unit 5173 includes a photoelectric conversion module for converting an optical signal into an electric signal. The communication unit 5173 provides the image signal after conversion into an electric signal to the image processing unit 5175.

Further, the communication unit 5173 transmits, to the camera head 5119, a control signal for controlling driving of the camera head 5119. Also the control signal may be transmitted by optical communication.

The image processing unit 5175 performs various image processes for an image signal in the form of RAW data transmitted thereto from the camera head 5119. The image processes include various known signal processes such as, for example, a development process, an image quality improving process (a bandwidth enhancement process, a super-resolution process, a noise reduction (NR) process and/or an image stabilization process) and/or an enlargement process (electronic zooming process). Further, the image processing unit 5175 performs a detection process for an image signal for performing AE, AF and AWB.

The image processing unit 5175 includes a processor such as a CPU or a GPU, and when the processor operates in accordance with a predetermined program, the image processes and the detection process described above can be performed. It is to be noted that, where the image processing unit 5175 includes a plurality of GPUs, the image processing unit 5175 suitably divides information relating to an image signal such that image processes are performed in parallel by the plurality of GPUs.

The control unit 5177 performs various kinds of control relating to image picking up of a surgical region by the endoscope 5115 and display of the picked up image. For example, the control unit 5177 generates a control signal for controlling driving of the camera head 5119. Thereupon, if image pickup conditions are inputted by the user, then the control unit 5177 generates a control signal on the basis of the input by the user. Alternatively, where the endoscope 5115 has an AE function, an AF function and an AWB function incorporated therein, the control unit 5177 suitably calculates an optimum exposure value, focal distance and white balance in response to a result of a detection process by the image processing unit 5175 and generates a control signal.

Further, the control unit 5177 controls the display apparatus 5155 to display an image of a surgical region on the basis of an image signal for which the image processes have been performed by the image processing unit 5175. Thereupon, the control unit 5177 recognizes various objects in the surgical region image using various image recognition technologies. For example, the control unit 5177 can recognize a surgical tool such as forceps, a particular living body region, bleeding, mist when the energy treatment tool 5135 is used and so forth by detecting the shape, color and so forth of edges of the objects included in the surgical region image. The control unit 5177 causes, when it controls the display apparatus 5155 to display a surgical region image, various kinds of surgery supporting information to be displayed in an overlapping manner with an image of the surgical region using a result of the recognition. Where surgery supporting information is displayed in an overlapping manner and presented to the surgeon 5181, the surgeon 5181 can proceed with the surgery more safety and certainty.

The transmission cable 5179 which connects the camera head 5119 and the CCU 5153 to each other is an electric signal cable ready for communication of an electric signal, an optical fiber ready for optical communication or a composite cable thereof.

Here, while, in the example depicted in the figure, communication is performed by wired communication using the transmission cable 5179, the communication between the camera head 5119 and the CCU 5153 may be performed otherwise by wireless communication. Where the communication between the camera head 5119 and the CCU 5153 is performed by wireless communication, there is no necessity to lay the transmission cable 5179 in the surgery room. Therefore, such a situation that movement of medical staff in the surgery room is disturbed by the transmission cable 5179 can be eliminated.

An example of the surgery room system 5100 to which the technology according to an embodiment of the present disclosure can be applied has been described above. It is to be noted here that, although a case in which the medical system to which the surgery room system 5100 is applied is the endoscopic surgery system 5113 has been described as an example, the configuration of the surgery room system 5100 is not limited to that of the example described above. For example, the surgery room system 5100 may be applied to a soft endoscopic system for inspection or a microscopic surgery system in place of the endoscopic surgery system 5113.

The technology according to the present disclosure may be applied to, for example, a display unit of an output device capable of visually or aurally notifying information among the above-described configurations.

[Others]

The present technology may also take the following configurations.

[A1]

A display apparatus comprising display elements formed on a substrate and arrayed in a two-dimensional matrix, the display elements each having a light emitting unit formed by stacking a lower electrode, an organic layer, and an upper electrode, wherein
the lower electrode and the organic layer are provided for each light emitting unit,
the substrate includes a groove formed in a part of the substrate positioned between adjacent light emitting units, the groove having a bottom surface and both side surfaces forming a gentle inclination angle with respect to the bottom surface, and
a protective film is formed in common on entire surface including an upper surface of the light emitting unit and an upper surface of the groove of the substrate.

[A2]

The display apparatus according to [A1], wherein
the groove of the substrate is formed by an etching method.

[A3]

The display apparatus according to [A2], wherein
a side wall surface of the organic layer is covered with a deposited film containing a substrate constituent as a component.

[A4]

The display apparatus according to [A3], wherein
the deposited film is formed on the both side surfaces of the groove of the substrate.

[A5]

The display apparatus according to [A3] or [A4], wherein
the deposited film contains a substrate constituent composed of a silicon compound as a component.

[A6]

The display apparatus according to any one of [A2] to [A5], wherein
the groove of the substrate is formed by a dry etching method.

[A7]

The display apparatus according to any one of [A1] to [A6], wherein
the lower electrode is formed such that an outer edge is not exposed to a side wall surface of the organic layer.

[A8]

The display apparatus according to [A7], wherein
the outer edge of the lower electrode is covered with an insulating layer.

[A9]

The display apparatus according to any one of [A1] to [A6], wherein
the lower electrode is formed such that an outer edge is exposed to a side wall surface of the organic layer.

[A10]

The display apparatus according to any one of [A1] to [A9], wherein
the upper electrode is provided for each light emitting unit.

[A11]

The display apparatus according to any one of [A1] to [A10], wherein
the protective film is constituted by an inorganic insulator.

[A12]

The display apparatus according to [A1], wherein
the protective film is made of any of silicon oxide, silicon nitride, and silicon oxynitride.

[B1]

A method for manufacturing a display apparatus,
the display apparatus including display elements formed on a substrate and arrayed in a two-dimensional matrix, the display elements each having a light emitting unit formed by stacking a lower electrode, an organic layer, and an upper electrode, the method comprising:
a first step of forming a stacked body in which materials constituting the lower electrode, the organic layer, and the upper electrode are sequentially stacked on the substrate;
a second step of removing a part of the stacked body corresponding to a portion between adjacent light emitting units and thereafter further forming a groove in a part of the substrate being exposed, the groove having a bottom surface and both side surfaces forming a gentle inclination angle with respect to the bottom surface; and
a third step of forming a protective film in common on entire surface including an upper surface of the light emitting unit and an upper surface of the groove of the substrate.

[B2]

The method for manufacturing a display apparatus according to [B1], wherein
in the first step, the stacked body in which materials constituting the organic layer and the upper electrode are sequentially stacked is formed after the lower electrode is formed for each light emitting unit on the substrate.

[B3]

The method for manufacturing a display apparatus according to [B2], wherein
the first step includes a step of covering an outer edge of the lower electrode with an insulating layer after the lower electrode is formed for each light emitting unit on the substrate.

[B4]

The method for manufacturing a display apparatus according to [B1], wherein
in the first step, the stacked body in which materials constituting the organic layer and the upper electrode are sequentially stacked is formed after a material layer constituting the lower electrode is formed on the substrate in common for every light emitting unit.

[B5]

The method for manufacturing a display apparatus according to [B4], wherein
the lower electrode is formed for each light emitting unit by removing a part of the stacked body corresponding to a portion between adjacent light emitting units in the second step.

[B6]

The method for manufacturing a display apparatus according to any one of [B1] to [B5], wherein
in the second step, the part of the stacked body corresponding to a portion between adjacent light emitting units is removed by an etching method, thereafter the groove is further formed in a part of the substrate being exposed, the groove having a bottom surface and both side surfaces forming a gentle inclination angle with respect to the bottom surface, and at the same time a side wall surface of the organic layer is covered with a deposited film generated by etching processing.

[C1]

An electronic device comprising a display apparatus,
the display apparatus including display elements formed on a substrate and arrayed in a two-dimensional matrix, the display elements each having a light emitting unit formed by stacking a lower electrode, an organic layer, and an upper electrode, wherein
the lower electrode and the organic layer are provided for each light emitting unit,
the substrate includes a groove formed in a part of the substrate positioned between adjacent light emitting units, the groove having a bottom surface and both side surfaces forming a gentle inclination angle with respect to the bottom surface, and
a protective film is formed in common on entire surface including an upper surface of the light emitting unit and an upper surface of the groove of the substrate.

[C2]

The electronic device according to [C1], wherein
the groove of the substrate is formed by an etching method.

[C3]

The electronic device according to [C2], wherein
a side wall surface of the organic layer is covered with a deposited film containing a substrate constituent as a component.

[C4]

The electronic device according to [C3], wherein
the deposited film is formed on the both side surfaces of the groove of the substrate.

[C5]

The electronic device according to [C3] or [C4], wherein
the deposited film contains a substrate constituent composed of a silicon compound as a component.

[C6]

The electronic device according to any one of [C2] to [C5], wherein
the groove of the substrate is formed by an etching method.

[C7]

The electronic device according to any one of [C1] to [C6], wherein
the lower electrode is formed such that an outer edge is not exposed to a side wall surface of the organic layer.

[C8]

The electronic device according to [C7], wherein
the outer edge of the lower electrode is covered with an insulating layer.

[C9]

The electronic device according to any one of [C1] to [C6], wherein
the lower electrode is formed such that an outer edge is exposed to a side wall surface of the organic layer.

[C10]

The electronic device according to any one of [C1] to [C9], wherein
the upper electrode is provided for each light emitting unit.

[C11]

The electronic device according to any one of [C1] to [C10], wherein
the protective film is constituted by an inorganic insulator.

[C12]

The electronic device according to [C1], wherein
the protective film is made of any of silicon oxide, silicon nitride, and silicon oxynitride.

### REFERENCE SIGNS LIST

1, 2, 3 DISPLAY APPARATUS
10, 10_{R}, 10_{G}, 10_{B} DISPLAY ELEMENT
20 SUBSTRATE
21 BASE MATERIAL
22 COMMON WELL REGION
23 ELEMENT ISOLATION REGION
24A, 24B PAIR OF SOURCE/DRAIN REGIONS
25 GATE INSULATING FILM
26 GATE ELECTRODE
27 INTERLAYER INSULATING FILM
28A, 28B SOURCE/DRAIN ELECTRODE
29 WIRING LAYER
31 VIA
41 LOWER ELECTRODE
42, 42_{R}, 42_{G}, 42_{B} ORGANIC LAYER
43 UPPER ELECTRODE
44 DEPOSITED FILM
45 PROTECTIVE FILM
50 PLANARIZATION LAYER
61, 61_{R}, 61_{G}, 61_{B} COLOR FILTER
62 COUNTER SUBSTRATE
241 LOWER ELECTRODE
242 INSULATING LAYER
341 LOWER ELECTRODE
GV GROOVE
BT BOTTOM SURFACE OF GROOVE
SL BOTH SIDE SURFACES OF GROOVE
SE SEAM
511 CAMERA BODY
512 PHOTOGRAPHING LENS UNIT
513 GRIP
514 MONITOR
515 VIEWFINDER
611 EYEGLASS-SHAPED DISPLAY UNIT
612 EAR HOOK
700 EYEGLASSES (EYEWEAR)
711 SEE-THROUGH HEAD MOUNTED DISPLAY
712 MAIN BODY
713 ARM
714 LENS BARREL

1. A display apparatus comprising display elements formed on a substrate and arrayed in a two-dimensional matrix, the display elements each having a light emitting unit formed by stacking a lower electrode, an organic layer, and an upper electrode, wherein
the lower electrode and the organic layer are provided for each light emitting unit,
the substrate includes a groove formed in a part of the substrate positioned between adjacent light emitting units, the groove having a bottom surface and both side surfaces forming a gentle inclination angle with respect to the bottom surface, and
a protective film is formed in common on entire surface including an upper surface of the light emitting unit and an upper surface of the groove of the substrate.

2. The display apparatus according to claim 1, wherein the groove of the substrate is formed by an etching method.

3. The display apparatus according to claim 2, wherein
a side wall surface of the organic layer is covered with a deposited film containing a substrate constituent as a component.

4. The display apparatus according to claim 3, wherein
the deposited film is formed on the both side surfaces of the groove of the substrate.

5. The display apparatus according to claim 3, wherein
the deposited film contains a substrate constituent composed of a silicon compound as a component.

6. The display apparatus according to claim 2, wherein
the groove of the substrate is formed by a dry etching method.

7. The display apparatus according to claim 1, wherein
the lower electrode is formed such that an outer edge is not exposed to a side wall surface of the organic layer.

8. The display apparatus according to claim 7, wherein
the outer edge of the lower electrode is covered with an insulating layer.

9. The display apparatus according to claim 1, wherein
the lower electrode is formed such that an outer edge is exposed to a side wall surface of the organic layer.

10. The display apparatus according to claim 1, wherein
the upper electrode is provided for each light emitting unit.

11. The display apparatus according to claim 1, wherein
the protective film is constituted by an inorganic insulator.

12. The display apparatus according to claim 11, wherein
the protective film is made of any of silicon oxide, silicon nitride, and silicon oxynitride.

13. A method for manufacturing a display apparatus,
the display apparatus including display elements formed on a substrate and arrayed in a two-dimensional matrix, the display elements each having a light emitting unit formed by stacking a lower electrode, an organic layer, and an upper electrode, the method comprising:
a first step of forming a stacked body in which materials constituting the lower electrode, the organic layer, and the upper electrode are sequentially stacked on the substrate;
a second step of removing a part of the stacked body corresponding to a portion between adjacent light emitting units and thereafter further forming a groove in a part of the substrate being exposed, the groove having a bottom surface and both side surfaces forming a gentle inclination angle with respect to the bottom surface; and
a third step of forming a protective film in common on entire surface including an upper surface of the light emitting unit and an upper surface of the groove of the substrate.

14. The method for manufacturing a display apparatus according to claim 13, wherein
in the first step, the stacked body in which materials constituting the organic layer and the upper electrode are sequentially stacked is formed after the lower electrode is formed for each light emitting unit on the substrate.

15. The method for manufacturing a display apparatus according to claim 14, wherein
the first step includes a step of covering an outer edge of the lower electrode with an insulating layer after the lower electrode is formed for each light emitting unit on the substrate.

16. The method for manufacturing a display apparatus according to claim 13, wherein
in the first step, the stacked body in which materials constituting the organic layer and the upper electrode are sequentially stacked is formed after a material layer constituting the lower electrode is formed on the substrate in common for every light emitting unit.

17. The method for manufacturing a display apparatus according to claim 16, wherein
the lower electrode is formed for each light emitting unit by removing a part of the stacked body corresponding to a portion between adjacent light emitting units in the second step.

18. The method for manufacturing a display apparatus according to claim 13, wherein
in the second step, the part of the stacked body corresponding to a portion between adjacent light emitting units is removed by an etching method, thereafter the groove is further formed in a part of the substrate being exposed, the groove having a bottom surface and both side surfaces forming a gentle inclination angle with respect to the bottom surface, and at the same time a side wall surface of the organic layer is covered with a deposited film generated by etching processing.

19. An electronic device comprising a display apparatus,
the display apparatus including display elements formed on a substrate and arrayed in a two-dimensional matrix, the display elements each having a light emitting unit formed by stacking a lower electrode, an organic layer, and an upper electrode, wherein
the lower electrode and the organic layer are provided for each light emitting unit,
the substrate includes a groove formed in a part of the substrate positioned between adjacent light emitting units, the groove having a bottom surface and both side surfaces forming a gentle inclination angle with respect to the bottom surface, and
a protective film is formed in common on entire surface including an upper surface of the light emitting unit and an upper surface of the groove of the substrate.
